(19) United States
(12) Patent Application Publication
(10) Pub. No.: US 2009/0233429 A1
(43) Pub. Date: Sep. 17, 2009

(54) SEMICONDUCTOR DEVICE MANUFACTURING METHOD AND SUBSTRATE PROCESSING APPARATUS

(76) Inventors: Dai Ishikawa, Toyama (JP); Sadayoshi Horii, Toyama (JP); Atsushi Sano, Toyama (JP)

Correspondence Address: KRATZ, QUINTOS & HANSON, LLP, 1420 K Street, N.W., Suite 400, WASHINGTON, DC, 20005, US

(21) Appl. No.: 12/293,884

(22) PCT Filed: May 16, 2007
(86) PCT No.: PCT/JP2007/060019

§ 371 Date: Sep. 22, 2008

(30) Foreign Application Priority Data
May 17, 2006 (JP) 2006-138231

(51) Int. Cl. H01L 21/31; H01L 21/28; C23C 16/513

(52) U.S. Cl. 438/585; 438/778; 118/723 R; 257/E21.24; 257/E21.19

(57) ABSTRACT

Nitrogen supplied into the high dielectric constant film is prevented from leaving from the film.

A semiconductor device manufacturing method, includes the steps of: nitriding a high dielectric constant film, formed on a substrate by using plasma, heat treating the nitrided high dielectric constant film, and transferring the heat treated substrate, wherein the nitriding step and the heat treating step are performed consecutively or simultaneously in the same substrate processing apparatus without exposing the substrate to air, and the step of transferring the substrate is performed while, the substrate is exposed to air.

### TECHNICAL FIELD

The present invention relates to a substrate processing apparatus and a semiconductor device manufacturing method.

The present invention for example is effectively utilized in processes for forming MOSFET (Metal oxide film semiconductor field effect transistor) gate stack structures on semiconductor wafers (hereinafter called “wafers”) on which integrated circuits containing semiconductor elements are formed in a method for manufacturing semiconductor integrated circuit devices (hereinafter called “ICs”).

### BACKGROUND ART

Silicon dioxide (SiO₂) film which is a thermal oxidized film made from silicon is utilized as the gate insulating film in MOSFET that is one of IC structural elements.

Along with recent progress in reducing the minimum IC fabrication dimensions, the gate insulating film must being made ever thinner and possess larger electrical capacitance.

However, the leak current becomes larger as the oxidized silicon film thickness becomes 2.0 nanometers or less, causing the concern that the oxidized silicon film serving as thermal oxidized film might not be usable as MOSFET gate insulating film.

Therefore, instead of using conventional thermal oxidized film, both domestic and overseas research institutions are carrying out research efforts aimed at a thicker physical film and a lower gate leak current achieved by suppressing the tunnel current by using a gate insulating film possessing a high, dielectric constant.

High dielectric constant films made from hafnium (Hf) and zirconium (Zr) oxides which are the most promising candidates for use in future LSI processes have the problem that the high dielectric constant film changes from an amorphous to a crystallized state even in heat treatment at comparatively low temperatures.

Changing to a crystallized state causes the problem that the leak current through the grain boundary increases and variations in the characteristics due to irregularities in the crystal orientation occur.

The technique of nitriding the high dielectric constant film is therefore applied as a method for improving the heat-resistance of the high dielectric constant film by raising the crystallized temperature in heat treatment.

Nitriding not only improves the thermal, stability but also renders the effect of reducing the leak current by improving the dielectric constant of the high dielectric constant film.

However, electrical and structural defects caused by nitriding, result in side effects that lower MOSFET reliability and degrade carrier mobility within the channel.

In order to extract the maximum effect from nitriding while suppressing the negative effects to a minimum, the supply of nitrogen to the vicinity of the interface with the silicon wafer that affects the reliability and electrical characteristics must be inhibited to increase the nitrogen concentration near the surface.

This type of depth distribution can be formed by plasma nitriding using a nitrogen species that is activated by the plasma.

The surface of the high dielectric constant gate insulating film formed on the wafer via several processes is on the other hand, exposed to air at the stage where transferred to the semiconductor manufacturing device for forming the electrodes.

The nitrogen supplied, into the high dielectric constant film by plasma nitriding leaves from the high dielectric constant film due to exposure, of the surface to air after processing.

Moreover, reduction in the amount of nitrogen, is higher in the area near the surface than in the area within the film.

The advantages obtained from plasma nitriding are therefore lost due to the reduction in the nitrogen concentration near the surface that has the effect of suppressing crystallization and lowering the leak current.

Moreover, the production stability declines since fluctuations in the time where the surface is exposed to

air cause fluctuations in the nitrogen concentration within the high dielectric constant film.

An attempt is therefore made to cluster the chamber for forming the gate insulating film and the chamber for forming the electrodes to process continuously in order to prevent exposing the gate insulating film to air.

### DISCLOSURE OF INVENTION

### Problems to be Solved by Invention

However, in processes for the dual metal gates, the electrodes made from different materials on NMOS and PMOS must be fabricated by processes such as lithography and dry etching. Clustering the chambers together in all these processes is impossible, so that exposing the gate insulating film to air was unavoidable.

Due to the above circumstances, a method is therefore needed that is capable of preventing nitrogen supplied into the high dielectric constant film from leaving from the film.

An object of the present invention is therefore to provide a substrate processing apparatus and a semiconductor device manufacturing method capable of preventing nitrogen supplied into the high dielectric constant film from leaving from the film.

### Means for Solving Problems

Typical aspects for resolving the aforementioned problems are described next.

(1) A semiconductor device manufacturing method comprising the steps of:

nitriding a high dielectric constant (High-k) film formed on a substrate by using plasma,

heat treating the nitrided high dielectric constant film, and

transferring the heat treated substrate,

wherein the nitriding step and the heat treating step are performed consecutively or simultaneously in the same substrate processing apparatus without exposing the substrate to air, and the step of transferring the substrate is. performed while the substrate is exposed to air.

(2) A semiconductor device manufacturing method comprising the steps of:

forming a high dielectric constant film on a substrate,

nitriding the high dielectric constant film by using plasma,

heat treating the nitrided high dielectric constant film, and

transferring the heat treated substrate,

wherein the step of forming the high, dielectric constant film, the nitriding step and the heat treating step are performed consecutively in the same substrate processing apparatus without exposing the substrate to air, and the step of transferring the substrate is performed while the substrate is exposed to air.

(3) A semiconductor device manufacturing method comprising the steps of;

forming an interfacial layer on a substrate, forming a high dielectric constant film on the interfacial layer,

nitriding the high dielectric constant film by using plasma,

heat treating the nitrided high dielectric constant film, and

transferring the heat treated substrate,

wherein the step of forming the interfacial layer, the step of forming the high dielectric constant film, the nitriding step and the heat treating step are performed consecutively in the same substrate processing apparatus without exposing the substrate to air, and the step of transferring the substrate is performed while the substrate is exposed to air.

(4) A semiconductor device manufacturing method comprising the steps of:

nitriding a high dielectric constant film formed on a substrate by using plasma,

heat treating the nitrided high dielectric constant film,

forming an electrode film on the heat treated high dielectric constant film,

exposing a portion of the high dielectric constant-film by removing a portion of the electrode film, and

transferring the substrate in a state where a portion of the high dielectric constant film is exposed,

wherein at least the nitriding step and the heat treating step are performed consecutively or simultaneously in the same substrate processing apparatus without exposing the substrate to air, and the step of transferring the substrate with a portion of the high dielectric constant film exposed is performed while the substrate is exposed to air.

(5) A semiconductor device manufacturing method comprising the steps of:

forming a high dielectric constant, film on a substrate, and

nitriding the high dielectric constant film by using plasma while heating the substrate,

wherein in the nitriding step, nitrogen ions are utilized as the main constituent of the substance for causing the nitriding, and the nitriding is performed at the nitriding processing temperature of performing the nitriding while repairing defects occurring due to the nitrogen ions in the high dielectric constant film.

(6) A substrate processing apparatus comprising:

a placement stand for mounting a substrate storage container for storing a substrate;

a prechamber that the substrate is carried in and carried out from;

a first processing chamber, a second processing chamber, and a third processing chamber for processing the substrate;

a first transfer chamber installed so as to connect in an airtight state to each of the prechamber, the first processing chamber, the second processing chamber and the third processing chamber, and including a first transfer device for transferring the substrate between the prechamber, the first processing chamber, the second processing chamber and the third processing chamber;

a second transfer chamber installed between the placement stand and the prechamber, and including a second transfer device for transferring the substrate between the prechamber and the substrate storage container mounted on the placement stand; and

a controller for controlling the above components so that the controller controls a continuous sequence of operations without exposing the substrate to air that include forming a high dielectric constant film on the substrate in the first processing chamber; transferring the substrate formed with the high dielectric constant film by the first transfer device from the first processing chamber via the first transfer chamber to the second processing chamber; nitriding the high dielectric constant film formed on the substrate by using plasma in the second processing chamber; transferring the nitrided substrate by the first transfer device from the second processing chamber via the first transfer chamber to the third processing chamber; and heat treating the nitrided high dielectric constant film in the third processing chamber, and controls to transfer the substrate that underwent the successive operations by the second transfer device in an atmosphere containing air, from the prechamber via the second transfer chamber to the substrate storage container mounted, on the placement stand.

(7) A substrate processing apparatus comprising:

a placement stand for mounting a substrate storage container for storing a substrate;

a prechamber that the substrate is carried in and carried out from;

a first processing chamber and a second processing chamber for processing the substrate;

a first transfer chamber installed so as to connect in an airtight state to each of the prechamber, the first, processing chamber and the second processing chamber, and including a first transfer device for transferring the substrate between the prechamber, the first processing chamber and the second processing chamber;

a second transfer chamber installed between the placement stand and the prechamber, and including a second transfer device for transferring the substrate between the prechamber and the substrate storage container mounted on the placement stand; and

a controller for controlling the above components so that the controller controls a continuous sequence of operations without exposing the substrate to air that include forming a high dielectric constant film on the substrate in the first processing chamber, transferring the substrate formed with the high dielectric constant film by the first transfer device from the first processing chamber via the first transfer chamber to the second processing chamber, nitriding the high dielectric constant film formed on the substrate by using plasma while heating the substrate in the second processing chamber wherein the processing pressure in the second processing chamber is set to a pressure where nitrogen ions are the main constituent of the substance for causing the nitriding, and the processing temperature is set to a temperature of performing the nitriding while repairing defects occurring due to the nitrogen ions in the high dielectric constant film, and controls to transfer the substrate that underwent the successive operations by the second transfer device in an atmosphere containing air, from the prechamber via the second transfer chamber to the substrate storage container mounted on the placement stand.

### Effect of Invention

The above first aspect continuously performs the nitrogen gas feed step and the annealing step without exposing the substrate to air and therefore renders the effect of preventing nitrogen supplied into the film possessing a high dielectric constant from leaving from within the film.

### BRIEF DESCRIPTION OF DRAWINGS

FIG. 1 is a flow chart, showing the gate stack forming process for forming gates on the MOSFET in an embodiment of

the present invention;

FIG. 2 is a plan cross sectional view showing the

cluster apparatus as an embodiment of the present invention;

FIG. 3 is a front cross sectional view showing the single-wafer ALD apparatus;

FIG. 4 is a front cross sectional view showing the MMT apparatus;

FIG. 5 is a front cross sectional view showing the RTP apparatus;

FIG. 6A through FIG. 6D are enlarged cross sectional views showing the wafer in each step;

FIG. 7A is an enlarged cross sectional, view showing the step for forming the NMOS electrode film;

FIG. 7B is an enlarged cross sectional view showing the step for forming through hole;

FIG. 8A is an enlarged cross sectional view showing the step for forming the PMOS electrode film;

FIG. 8B is an enlarged cross sectional view showing the planarizing step;

FIG. 9 is an enlarged cross sectional view showing the patterning step for the NMOS electrode and the PMOS electrode;

FIG. 10A through FIG. 10E are diagrams showing flaws occurring due to the plasma nitriding and the repair of flaws due to annealing;

FIG. 11 is a graph showing the interrelation of the annealing temperature and nitrogen concentration;

FIG. 12 is a graph showing the nitrogen distribution in the nitrided hafnium silicate film left standing in the air for a five day period after film forming;

FIG. 13 is a flow chart showing the gate stack forming process for forming gates on the MOSFET in another embodiment of the present invention;

FIG. 14 is a flow chart showing the gate stack forming process for forming gates on the MOSFET in still another embodiment of the present invention.

### BEST MODE FOR CARRYING OUT THE INVENTION

An embodiment of the present invention is described next while referring to the drawings.

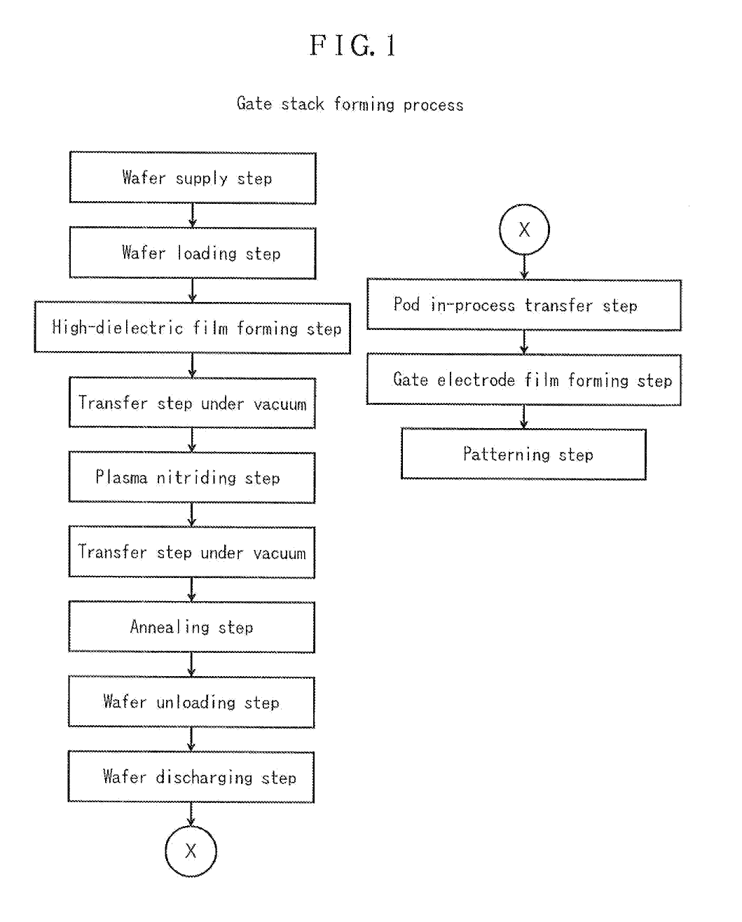

FIG. 1 is a flow chart showing the process for forming the MOSFET gate stack in the IC production method of an embodiment of the present invention.

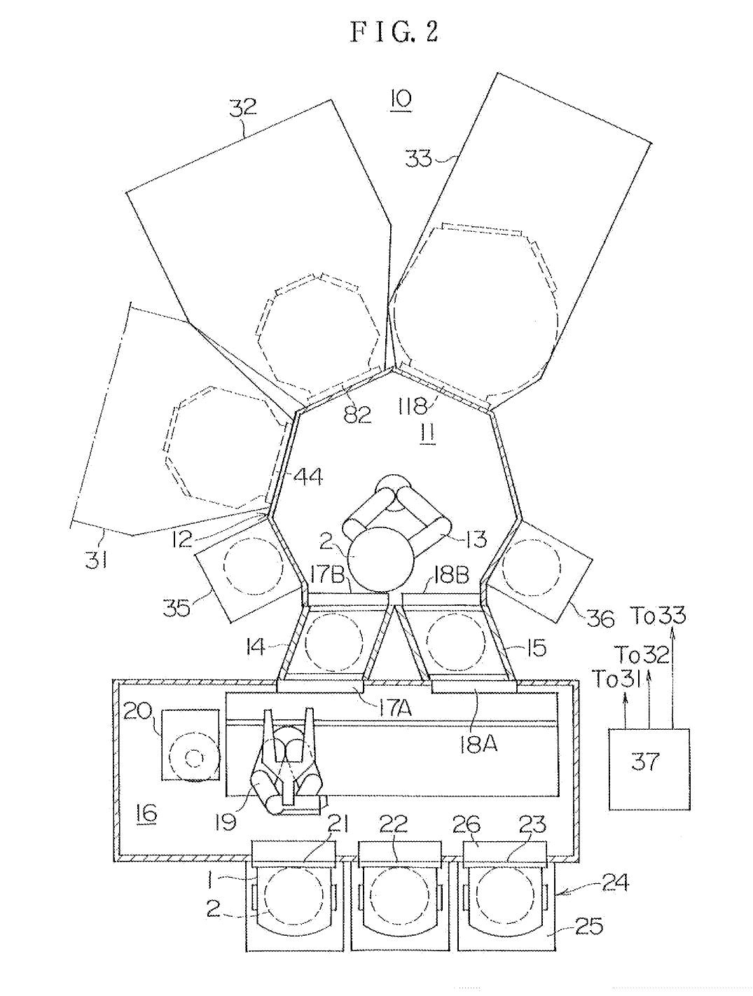

FIG. 2 and onward are drawings showing the substrate processing apparatus of the first embodiment of the present invention.

The substrate processing apparatus of the first embodiment of the present invention is described first.

In this embodiment, the substrate processing apparatus of the present invention is structurally a cluster apparatus shown in FIG. 2; and functionally is configured to be used in the MOSFET gate stack forming process.

The cluster apparatus in this embodiment utilizes a FOUP (front opening unified pod. hereinafter called “pod”) 1 as the wafer transfer carrier (substrate storage container) for transferring wafers 2 as the substrate.

As shown in FIG. 2, the cluster apparatus 10 contains a first wafer transfer chamber (hereinafter called “negative pressure transfer chamber”) 11 functioning as the transfer chamber with a structure capable of withstanding a pressure (negative pressure) below atmospheric pressure. A case of the negative pressure transfer chamber 11 (hereinafter called “the negative pressure transfer chamber case”) 12 is formed in a box shape, sealed at both the top and bottom ends and having seven sides as seen from a plan view.

A wafer transfer device (hereinafter, called “negative pressure transfer device”) 13 functioning as the transfer device for transferring the wafers 2 under a negative pressure is installed at the center section of the negative pressure transfer chamber 11. This negative pressure transfer device 13 is made up of a SCARA robot (selective compliance assembly robot arm SCARA).

A carry-in pre-chamber (hereinafter called “carry-in chamber”) 14 and a carry-out pre-chamber (hereinafter, called “carry-out chamber”) 15 are connected adjacently to each other on the long side wall among the seven side walls in the negative pressure transfer chamber 12.

The cases for the carry-in chamber 14 and the carry-out chamber 15 are formed in a box shape sealed at both the top and bottom ends and respectively in a roughly diamond shape as seen from a plan view, and also formed in a load-lock chamber structure for withstanding negative pressure.

A second wafer transfer chamber (hereinafter, called “positive pressure transfer chamber”) 16 structured to maintain a pressure of atmospheric pressure or above (hereinafter, called “positive pressure”) is connected adjacently to the side, opposite the negative pressure transfer chamber 11 of the carry-in chamber 14 and the carry-out chamber 15. The case for the positive pressure transfer chamber 16 is formed in a box shape sealed at the top and bottom ends and possessing a lateral rectangular shape as seen from a plan view.

A gate valve 17A is installed at the boundary between the carry-in chamber 14 and the positive pressure transfer chamber 16. A gate valve 17B is installed between the negative pressure transfer chamber 11 and the carry-in chamber 14.

A gate valve 18A is installed at the boundary between the carry-out chamber 15 and the positive pressure transfer chamber 16. A gate valve 18B is installed between the carry-out chamber 15 and the negative pressure chamber 11.

A second wafer transfer device (hereinafter, called “positive pressure transfer device”) 19 is installed in the positive pressure transfer chamber 16 for transferring the wafers 2 under a positive pressure. This positive pressure transfer device 19 is made up of a SCARA type robot.

The positive pressure transfer device 19 is structured to be raised and lowered by an elevator installed in the positive pressure transfer chamber 16 and also to be moved in the left and right directions by a linear actuator.

A notch aligner device 20 is installed on the left end of the positive pressure transfer chamber 16.

Three wafer carry-in/out ports 21, 22, 23 are formed while arrayed adjacent to each other on the front wall of the positive pressure transfer chamber 16. These wafer carry-in/out ports 21, 22, 23 are formed so as to carry the wafers 2 in and out from the positive pressure transfer chamber 16.

Pod openers 24 are installed in the respective wafer carry-in/out ports 21, 22, 23.

The pod opener 24 contains a placement stand 25 for placing the pod 1; and a cap fitter/remover 26 for removing and fitting the cap for the pod 1 mounted on the placement stand 25. The cap fitter/remover 26 removes and fits the cap for the pod 1 mounted on the placement stand 25 to open and close the wafer loading/unloading opening of the pod 1.

An in-process transfer device (RGV) not shown in the drawing, supplies and removes the pod 1 to and from the placement stand 25 of the pod opener 24.

As shown in FIG. 2, a first processing unit 31 and a second processing unit 32 and a third processing unit 33 are connected adjacently to each other on three side walls among the seven side walls of the negative pressure transfer chamber case 12 at positions opposite the positive pressure transfer chamber 16.

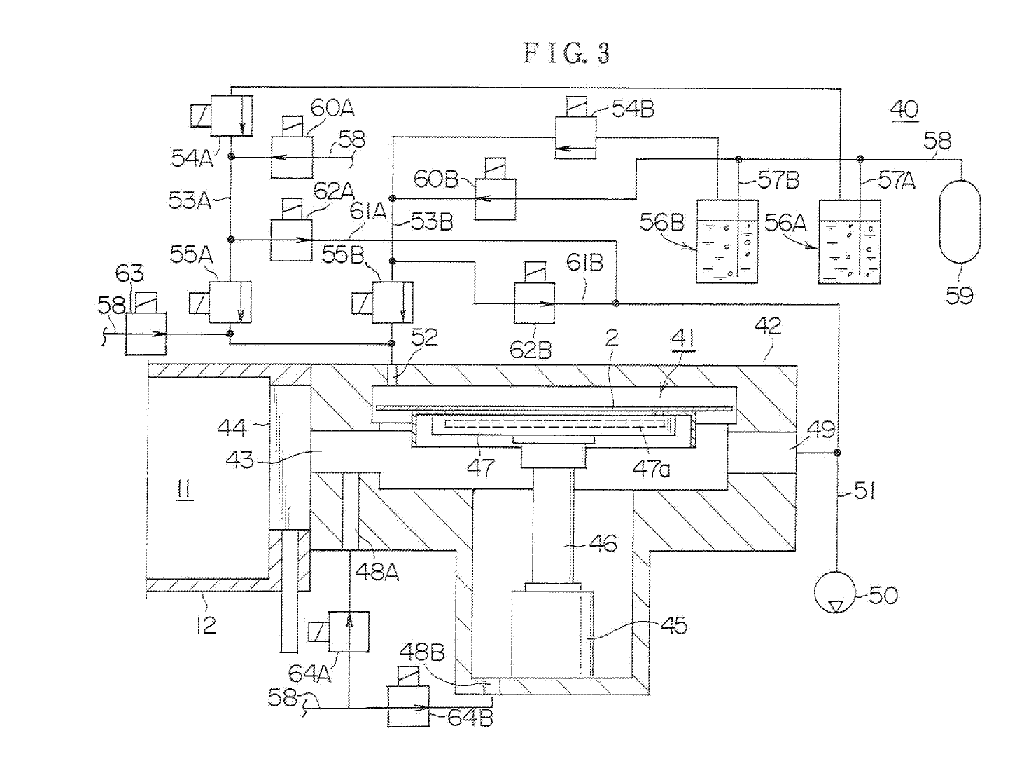

A gate valve 44 (See FIG. 3) is installed between the first processing unit 31 and the negative pressure transfer chamber 11.

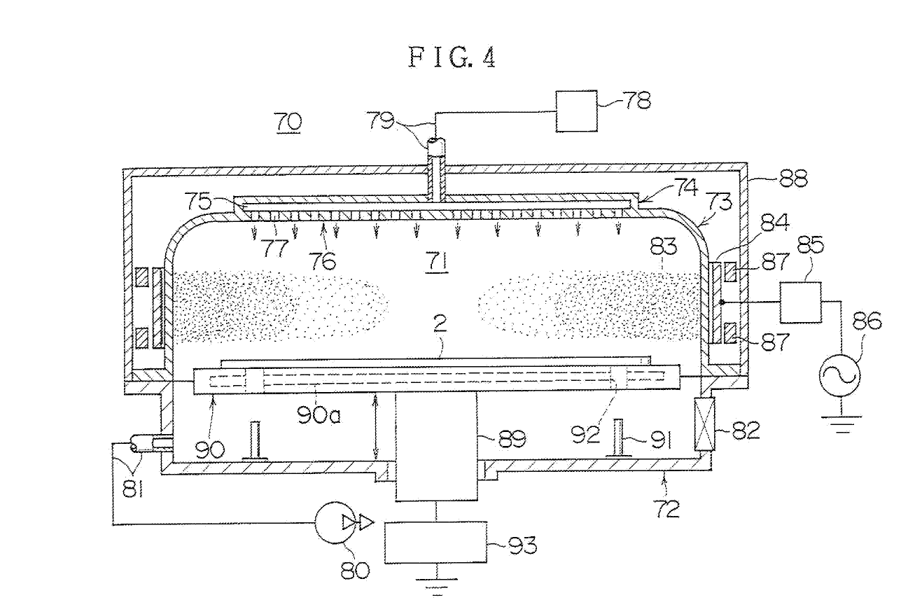

A gate valve 82 (See FIG. 4) is installed between the second processing unit 32 and the negative pressure transfer chamber 11.

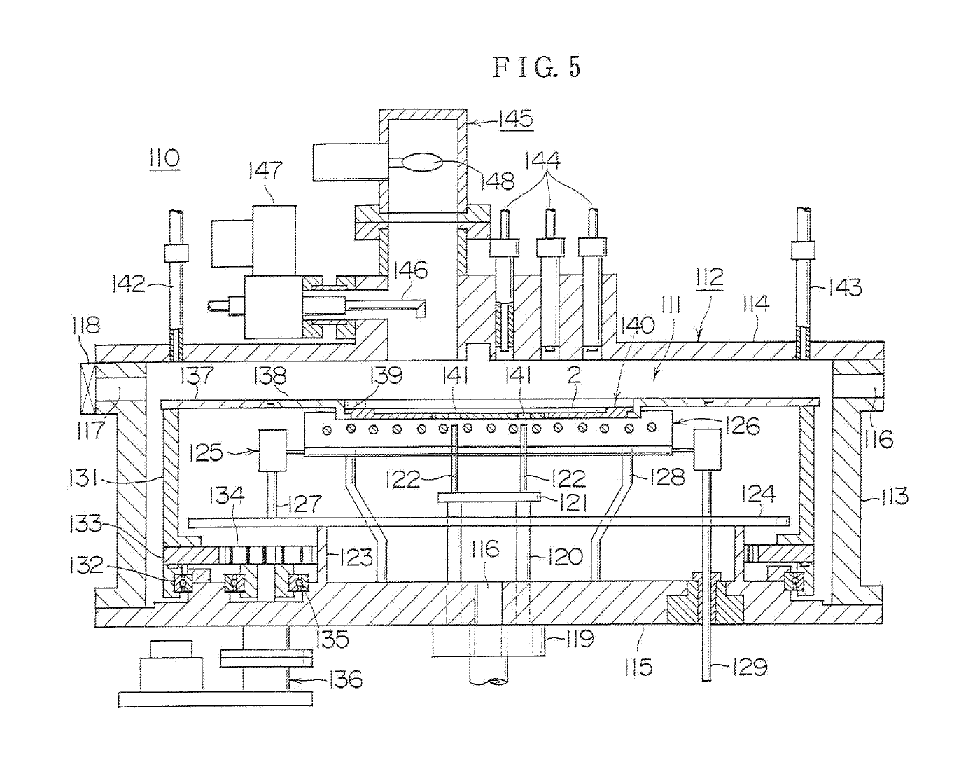

A gate valve 118 (See FIG. 5) is installed between the third processing unit 33 and the negative pressure transfer chamber 11.

A first cooling unit 35 and a second cooling unit 36 are respectively connected to two other side walls among the seven walls of the negative pressure transfer chamber case 12. The first cooling unit 35 and the second cooling unit 36 both cool the wafer 2 whose processing is finished.

The cluster apparatus 10 contains a controller 37 for controlling the sequence flow in a unified manner as described later on.

Performing the gate stack forming process shown in FIG. 1 by using the cluster apparatus 10 configured as described above is related next.

In the wafer loading step shown in FIG. 1, the cap fitter/remover 26 removes the cap of the pod 1 supplied to the placement stand 25 of the cluster apparatus 10, and opens the wafer loading/unloading opening of the pod 1.

When the pod 1 is opened, the positive pressure transfer device 19 installed in the positive pressure transfer chamber 16 picks up the wafer 2 one at a time from the pod 1 by way of the wafer loading/unloading opening, supplies it to the carry-in chamber 14, and transfers the wafer 2 to the temporary placement stand for the carry-in chamber.

The positive pressure transfer chamber 16 side of the carry-in chamber 14 is opened by the gate valve 17A during this transfer operation. Also, the negative pressure transfer chamber 11 side of the carry-in chamber 14 is closed by the gate valve 17B. The pressure within the negative pressure transfer chamber 11 is maintained for example at 100 Pa.

In the wafer loading step shown in FIG. 1, the gate valve 17A closes the positive pressure transfer chamber 16 side of the carry-in chamber 14. An exhaust device (not shown in drawing) exhausts the carry-in chamber 14 to a negative pressure.

The gate valve 17B opens the negative pressure transfer chamber 11 side of the carry-in chamber 14, when the interior of the carry-in chamber 14 is depressurized to a preset pressure value.

Next, the negative pressure transfer device 13 of the negative pressure transfer chamber 11 picks up the wafer 2 one at a time from the temporary placement stand for the carry-in chamber and carries it into the negative pressure transfer chamber 11.

The gate valve 17B then closes the negative pressure transfer chamber 11 side of the carry-in chamber 14.

The gate valve 44 of the first processing unit 31 then opens, and the negative pressure transfer device 13 then transfers the wafer 2 into the first processing unit 31 to perform the high dielectric constant film forming step shown in FIG. 1, and loads it into the processing chamber of the first processing unit 31.

The interior of the carry-in chamber 14 and the negative pressure transfer chamber 11 are exhausted beforehand in order to remove oxygen and moisture from the interior, when loading the wafer into the first processing unit 31, to ensure that external oxygen and moisture are prevented from penetrating into the processing chamber of the first processing unit 31 during carry-in of the wafer to the first processing unit 31.

In this embodiment, the first processing unit 31 is structurally a single-wafer warm wall type substrate processing apparatus as shown in FIG. 3; and functionally is an ALD (Atomic Layer Deposition) apparatus (hereinafter, called “ALD apparatus”) 40.

As shown in FIG. 3, the ALD apparatus 40 contains a case 42 forming a processing chamber 41. The case 42 contains a heater (not shown in drawing) for heating the wall surfaces of the processing chamber 41.

A wafer carry-in/out port 43 is formed on the boundary with the negative pressure transfer chamber 11 in the case 42. The gate valve 44 opens and closes the wafer carry-in/out port 43.

An elevator drive device 45 for raising and lowering a rise/lower shaft 46 is installed on the bottom of the processing chamber 41. A holder jig 47 for holding the wafer 2 is supported horizontally on. the top end of the rise/lower shaft 46.

A heater 47a for heating the wafer 2 is installed on the holding jig 47.

Purge gas supply ports 48A, 48B are respectively formed on the bottom walls of the processing chamber 41 and the wafer carry-in/out port 43. An argon gas supply line 58 as the purge gas supply line connects respectively by way of a stop valve 64A and a stop valve 64B to both the purge gas supply ports 48A, 48B. An argon gas supply source 59 connects to the argon gas supply line 58.

An exhaust port 49 is formed on a section on the side opposite the wafer carry-in/out port 43 of the case 42. An exhaust line 51 connected to an exhaust device 50 is connected to the exhaust port 49.

A process gas supply port 52 is formed to connect to the processing chamber 41 on the ceiling wall of the case 42. A first process gas supply line 53A and a second process gas supply line 53B are connected to the process gas supply port 52.

A first bubbler 56A connects to the first process gas supply line 53A by way of an upstream stop valve 54A and a downstream stop valve 55A. A bubbling pipe 57A for the first bubbler 56A connects to the argon gas supply line 58 that is connected to the argon gas supply source 59.

The argon gas supply line 58 is connected by way of a stop valve 60A between the upstream stop valve 54A and the downstream stop valve 55A on the first process gas supply line 53A. The upstream end of a vent line 61A is connected between the downstream stop valve 55A and the connection point for the argon gas supply line 58 in the first process gas supply line 53A. The downstream end of the vent line 61A is connected by way of the stop valve 62A to the exhaust line 51 connected to the exhaust device 50,

The argon gas supply line 58 is connected by way of a stop valve 63 on the side farther downstream than the downstream stop valve 55A on the first process gas supply line 53A.

A second bubbler 56B connects to the second, process gas supply line 53B by way of an upstream stop valve 54B and a downstream stop valve 55B. A bubbling pipe 57B for the second bubbler 56B is connected to the argon gas supply line 58 that is connected to the argon gas supply source 59.

The argon gas supply line 58 is connected by way of a stop valve 60B between the upstream stop valve 54B and the downstream stop valve 55B on the second, process gas supply line 53B. The upstream end of a vent line 61B is connected between the downstream stop valve 55B and the connection point for the argon gas supply line 58 in the second process gas supply line 53B. The downstream, end of the vent line 61B is connected by way of a stop valve 62B to the exhaust line 51 connected, to the exhaust device 50,

The step of forming the high dielectric constant film shown in FIG. 1 is next described for the case where forming hafnium silicate (HfSiO) film as the high dielectric constant (High-k) film on the wafer 2 by the ALD method using the ALD apparatus 40 structured as related above.

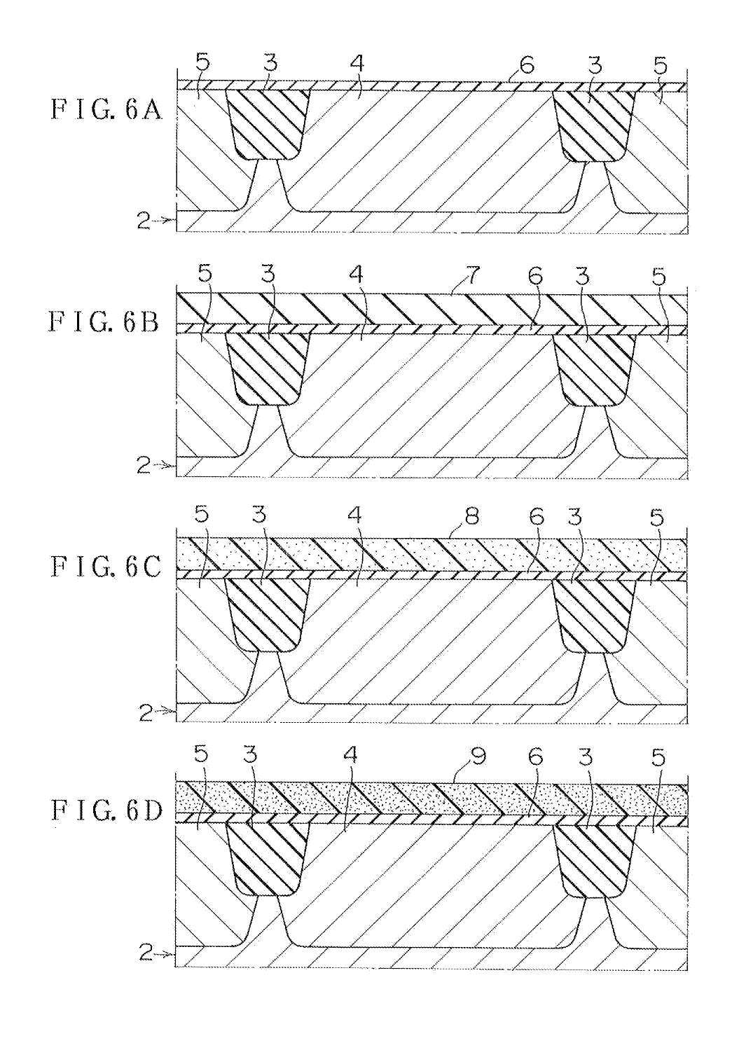

The structure of the wafer 2 prior to forming the high dielectric constant film is shown in FIG. 6A.

Namely, a device isolation region 3 is formed on the silicon wafer 2. A P-well region 4 and an N-well region 5 are formed on the active area separated by this device isolation region 3. An interfacial silicon oxide film 6 is formed as an interfacial layer on the surface layer of the silicon wafer 2.

Materials containing hafnium atoms (Hf) when forming a hafnium silicate (HfSiG) film as the high dielectric constant film use for example the following materials.

TDMAH(Hf[N(CH₃)₂]₄: Tetrakis dimethyl amino hafnium)

TDEMAH (Hf[N(C₂H₅)₂]₄: Tetrakis diethyl amino hafnium)

TEMAH(Hf[N(CH₃)(C₂H₅)]₄: Tetrakis ethyl methyl amino hafnium)

Hf—OtBu(Hf[OC(CH₃)₃]₄: Tetra tertiary butoxy hafnium)

Hf—MMP₄(Hf[OC(CH₃)₂CH₂OCH₃]₄: Tetrakis (1-metoxy-2-methyl-2-propoxy)hafnium).

Materials containing silicon atoms (Si) use for example the following materials.

Si—OtBu(Si[OC(CH₃)₃]₄: Tetra tertiary butoxy silicon)

Si—MMP₄(Si[OC (CH₃)₂CH₂OCH₃]₄: Tetrakis (1-methoxy-2-methyl-2-propoxy)silicon),

TEOS(Si[OC₂H₅]₄: Tetraethoxysilane).

These materials are fluids at room temperature, and have a high evaporation pressure. They are utilized as a material gas after vaporizing by bubbling.

The ALD apparatus 40 of this embodiment utilizes the first bubbler 56A for vaporizing the hafnium fluid material and silicon fluid material.

In this embodiment, the hafnium fluid material and silicon fluid material are mixed together and this mixed fluid material then stored in the bubbler 56A.

The flow rate for the argon gas used for bubbling in this first bubbler 56A is for example 0.5 SLM to 1 SLM (standard liter per minute).

The oxidizer for example is a gas containing oxygen atoms such as ozone (O₃) or water vapor (H₂O). If using ozone, then an ozone generator is used.

The ALD apparatus 40 of this embodiment utilizes water vapor as the oxidizer. The second bubbler 56B is utilized to generate this water vapor. The argon gas flow rate used for bubbling in this second, bubbler 56B for example is 0.5 SLM to 1 SLM.

The gate valve 44 opens and the wafer 2 on which a hafnium silicate film is to be formed is carried into the processing chamber 41 of the ALD apparatus serving as the first processing unit 31. When the wafer 2 is mounted in the holding jig 47 as shown in FIG. 3, the gate valve 44 closes the wafer carry-in/out port 43.

When the gate valve 44 is closed, the exhaust device 50 exhausts the interior of the processing chamber 41 to a specified pressure.

The internal heater 47a in the holding jig 47 then heats the wafer 2 to a specified temperature within a range from 150 to 500 degrees C.,

The stop valves 54A, 55A, 54B and 55B are all closed at the time that the wafer 2 is carried in, and the stop valves 60A, 62A, 60B and 62B are all open.

Here, besides closing the stop valves 60A, 55A, 60B and 55B to prepare the material to be supplied, the stop valves 54A, 62A, 54B and 62B are opened in order to fill the material mixture of vaporized hafnium material and silicon material as well as the water vapor respectively into the first process gas supply line 53A and the second process gas supply line 53B.

The stop valve 63 opens to supply argon gas as the purge gas into the processing chamber 41. Moreover, opening the stop valves 64A, 64B supplies argon gas as the purge gas from the purge gas supply ports 48A, 48B into the space below the holding jig 47 within the processing chamber 41 at a flow rate for example of 0.1 SLM to 1.5 SLM.

The pressure within the processing chamber 41 is adjusted between 10 Pa to 100 Pa.

After the temperature of the wafer 2 has stabilized, the next steps (1) through (4) as one cycle are repeated until the hafnium silicate film has a target film thickness.

(1) In the material supply step performed after the temperature of the wafer 2 has stabilized, the stop valve 62A is closed and the stop valve 55A is opened. This state is maintained unchanged for 0.5. to 5 seconds, and the material mixture of vaporized hafnium material and silicon material is supplied into the processing chamber 41.

Thus, the material mixture of vaporized hafnium material and silicon material is adsorbed on the surface of the wafer 2.

(2) Next, in the material exhaust step, the stop valve 54 is closed and the stop valve 60A is opened. This state is maintained unchanged for 0.5 to 10 seconds, and the material supplied into the first process gas supply line 53 and into the processing chamber 41 is exhausted.

Next, the stop valves 60A, 55A are closed, and the stop valves 54A, 62A are opened, and the material mixture of vaporized hafnium material and silicon material is filled into the first process gas supply line 53A.

(3) In the oxidizing step the stop valve 62B is closed and the stop valve 55B is opened simultaneous with filling the material mixture of vaporized hafnium material and silicon, material into the first process gas supply line 53A. This state is maintained unchanged for 0.5 to 15 seconds, and water vapor as an oxidizer is supplied into the processing chamber 41.

The material mixture of vaporized hafnium material and silicon material adsorbed on the surface of the wafer 2 in the step (1) reacts with the water vapor to form a hafnium silicate film with a film thickness of approximately one angstrom (Å) on the surface of the wafer 2.

(4) Next, as an oxidizer exhaust step, the stop valve 54B is closed, and the stop valve 60B is opened. This state is maintained unchanged for 0.5 to 15 seconds, and the oxidizer that, was supplied into the interior of the second process gas supply line 53B and into the processing chamber 41 is exhausted.

The stop valves 60B, 55B are next closed, the stop valves 54B, 62B are opened, and water vapor is filled into the second process gas supply line 53B.

Usually, if forming film by the ALD method, then a film with a thickness of about one angstrom (Å) is formed in one cycle, so 20 to 30 cycles are required in order to obtain the target film thickness of 20 Å to 30 Å. If one cycle requires 5 to 10 seconds, then forming the hafnium silicate film with the target film thickness will require 2 to 6 minutes.

In this way, the hafnium silicate film 7 serving as the high dielectric constant film is formed on the wafer 2 as shown in FIG. 6B.

When finished forming the hafnium silicate film, the gate valve 44 opens, and the negative pressure transfer device 13 unloads the processed wafer 2 from the first processing unit 31 to the negative pressure transfer chamber 11 maintained at a negative pressure.

Then, after the gate valve 44 is closed, the gate valve 82 is opened, and the negative pressure transfer device 13 loads the wafer 2 to the second processing unit 32 to implement the plasma nitriding step shown in FIG. 1, and loads it into the processing chamber of the second processing unit 32.

This embodiment utilizes a MMT (Modified Magnetron Type) apparatus 70 shown in FIG. 4 as the second processing unit 32.

The MMT apparatus 70 contains a processing chamber 71 as shown in FIG. 4. The processing chamber 71 is made up of a lower container 72, and an upper container 73 covering the top of the lower container 72.

The upper container 73 is formed in a dome shape from oxidized aluminum or quartz. The lower container 72 is formed from aluminum.

A shower head 74 forming a buffer chamber 75 serving as a gas dispersion space is provided in the upper section of the upper container 73. A shower plate 76 containing gas spray holes 77 as spray vents for spraying gas is provided on the lower wall. A gas supply line 79 connecting to a gas supply device 78 connects to the upper wall of the shower head 74.

An exhaust line 81 connecting to an exhaust device 80, is connected to a section of the side wall of the lower container 72.

The gate valve 82 serving as a sluice valve is installed on another position of the side wall of the lower container 72. The negative pressure transfer device 13 carries the wafer 2 in and out of the processing chamber 71 when the gate valve 82 opens. The processing chamber 71 is maintained airtight while the gate valve 82 is closed.

A tube shaped (preferably cylinder shaped) tubular electrode 84 serving as a discharge means to excite the reaction gas is installed concentrically on the outer side of the upper container 73. The tubular electrode 84 encloses a plasma generating region 83 of the processing chamber 71. An RF power supply 86 for applying RF (high frequency) power is connected to the tubular electrode 84 by way of an impedance matcher 85 for matching the impedance.

Tube-shaped (preferably cylinder shaped) tubular magnets 87 serving as a magnetic field forming means are installed concentrically on the outer side of the tubular electrode 84. The tubular magnets 87 are installed respectively near the upper and lower ends on the outer surface of the tubular electrode 84.

The upper and lower tubular magnets 87, 87 contain magnetic poles on both ends (inner circumferential end and outer circumferential end) along the radius of the processing chamber 71. The magnetic poles of the upper and lower tubular magnets 87, 87 are set facing opposite directions. The magnetic poles in the inner circumferential section are opposing poles. Magnetic lines of force are therefore formed along the tubular axis in the inner circumferential surface of the tubular electrode 84.

A shield plate 88 for effectively blocking electrical fields and magnetic fields is installed on the periphery of the tubular electrode 84 and the tubular magnets 87. The shield plate 88 blocks the electrical fields and magnetic fields formed by the tubular electrode 84 and the tubular magnet 87 to prevent adverse effects on the external environment, etc.

A susceptor elevating axis 89 raised and lowered vertically by an elevator is supported for vertical up and down movement in the center section of the lower container 72. A susceptor 90 as a holding means for holding the wafers is installed horizontally on the upper end on the processing chamber 71 side of the susceptor elevating axis 89.

The susceptor elevating axis 89 is insulated from the lower container 72. Three pushup pins 91 are affixed perpendicularly outwards of the susceptor elevating axis 89 on the bottom side of the lower container 72.

The three pushup pins 91 are inserted from below through three insertion holes 92 formed in the susceptor 90 to push up the wafer 2 being held on the susceptor 90 when the susceptor elevating axis 89 is lowering.

The susceptor 90 is a dielectric piece made of quartz and formed in a disk shape with a diameter larger than the wafer 2. The susceptor 90 contains an internal heater 90a.

An impedance matcher 93 for adjusting the impedance is electrically connected to the susceptor 90. The impedance matcher 93 is made up of a coil and a variable condenser and controls the voltage potential on the wafer 2 by way of the susceptor 90 by regulating the capacitance on the variable condenser and the number of turns on the coil.

The case where performing the plasma nitriding step as shown in FIG. 1, by using the MMT apparatus 70 configured as described above when adding nitrogen (N) to the hafnium silicate film is described next.

In the first processing unit 31, when the gate valve 82 opens, the negative pressure transfer device 13 carries the wafer 2 formed with a hafnium silicate film into the processing chamber 71 of the MMT apparatus 70 that is the second processing unit 32, and transfers it to the upper end of the three pushup pins 91.

When the negative pressure transfer device 13 that transferred the wafer 2 onto the pushup pins 91, retreats to outside the processing chamber 71, the gate valve 82 closes, the susceptor elevating axis 89 raises the susceptor 90, and the wafer 2 is delivered from on top of the pushup pins 91 to the susceptor 90 as shown in FIG. 4.

The exhaust device 80 exhausts the interior of the processing chamber 71 so as to reach a specified pressure within a range of 0.5 Pa to 200 Pa, with the processing chamber 71 sealed in an airtight state.

The heater 90a of the susceptor 90 is preheated. The heater 90a heats the wafer 2 held on the susceptor 90 to the specified processing temperature within a range of room temperature to 950 degrees C. The processing temperature is for example described as within a specified temperature range of 100 to 500 degrees C.

When the wafer 2 is heated to the processing temperature, the gas supply device 78 feeds a gas containing nitrogen atoms such as nitrogen gas (N₂) or ammonia (NH₃) gas in a shower state at a flow rate of 0.1 SLM to 2 SLM by way of the gas supply line 79 and the gas spray holes 77 of the shower plate 76 into the processing chamber 71.

The high-frequency RF power supply 86 next applies high frequency (RF) power of 50 to 700 watts to the tubular-electrode 84 by way of the impedance matcher 85. The impedance matcher 85 controls the RF power so that the reflected wave is minimal.

Magnetron discharge occurs due to the effects of the magnetic field of the tubular magnets 87, 87, and the charge is trapped in the space above the wafer 2, generating a high density plasma in the plasma generating region 83.

The surface of the wafer 2 on the susceptor 90 is then plasma-processed by this high density plasma.

A nitrogen quantity that matches the above processing conditions is added to the hafnium silicate film formed on the wafer 2. The hafnium silicate film 7 then becomes the nitrided hafnium silicate (HfSiON) film 8 as shown in FIG. 6B and FIG. 6C.

This processing time is normally 30 seconds to 5 minutes.

Plasma-treating gas containing nitrogen generates nitrogen ions (N+, N−), nitrogen radicals (N*), and electrons (e), etc.

When the pressure is low (for example, 2 Pa or less) during the plasma nitriding, then the main constituent of the nitriding is ions, and the nitrogen content in the High-k film is comparatively large.

Conversely when the pressure is high (for example, seven dozen Pascals or more) during plasma nitriding, then the main constituent of the nitriding is nitrogen radicals, and the nitrogen content in the High-k film becomes low.

In this embodiment, the plasma nitriding by the MMT apparatus is performed under the condition of low pressure. Nitrogen ions contribute most to the nitriding and the nitrogen radicals contribute little to the nitriding.

The nitrogen content within the High-k film becomes large in this case but damage to the High-k film is large compared to the case when utilizing nitrogen radicals.

In this embodiment, mainly the nitrogen ions contribute to the nitriding so that the nitrogen concentration of the High-k film can be regulated by adjusting the bias applied to the wafer.

In contrast, when plasmatized gas containing nitrogen is supplied to the wafer by way of an ion trapper (metallic plate), the nitrogen ions are removed by the ion trapper so that only electrically neutral nitrogen radicals are supplied to the wafer. In other words, only the nitrogen radicals contribute to the nitriding.

In this case, the nitrogen content in the High-k film becomes small. There is little damage to the High-k film compared to when utilizing nitrogen ions.

The nitrogen radicals are electrically neutral so that the nitrogen concentration of the High-k. film cannot, be regulated even by adjusting the bias applied to the wafer.

The gate valve 82 opens when a specified pre-set processing time elapses in the MMT apparatus 70, and the negative pressure transfer device 13 carries the wafer 2 formed with the nitrided hafnium silicate film from the processing chamber 71 into the negative pressure transfer chamber 11 in a sequence that is the reverse of the loading operation (wafer unloading).

Next, after the gate valve 82 closes, the gate valve 118 opens, and the negative pressure transfer device 13 transfers the wafer 2 to the third processing unit 33 for performing the annealing step shown in FIG. 1, and loads it into the processing chamber of the third processing unit 33 (wafer loading).

In this embodiment, a RTF (Rapid Thermal Processing) apparatus 110 as shown in FIG. 5 is utilized in the third processing unit 33 for performing the annealing step.

The RTP apparatus 110 as shown in FIG. 5 contains a case 112 that forms a processing chamber 111 for processing the wafer 2. This case 112 is made up of a cup 113 formed in a cylindrical shape open on the bottom and top surfaces, a top plate 114 formed in a disk shape for sealing the top surface opening of the cup 113, and a bottom plate 115 in a disk shape for sealing the bottom surface opening of the cup 113. The case 112 is formed in cylindrical hollow shape.

An exhaust port 116 is formed on a portion of the side wall of the cup 113 so as to connect the inside and outside of the processing chamber 111. An exhaust device (not shown in drawing) connected to the exhaust port 116 exhausts the processing chamber 111 to below atmospheric pressure (hereinafter called “negative pressure”).

A wafer carry-in/out port 117 for carrying the wafer 2 into and out of the processing chamber 111 is formed at a position opposite the exhaust port 116 on the side wail of the cup 113. The gate valve 118 opens and closes the wafer carry-in/out port 117.

An elevator drive device 119 is installed on the center line on the lower surface of the bottom plate 115. This elevator drive device 119 raises and lowers an elevator shaft 120 inserted into the bottom plate 115 and structured for free sliding vertical movement relative to the bottom plate 115.

An elevator plate 121 is affixed horizontally on the top edge of the elevator shaft 120. Multiple (usually three or four pins) lifter pins 122 are erected perpendicularly on the upper surface of the elevator plate 121. Each of these lifter pins 122 rises or lowers along with the rise and lowering of the elevator plate 121 so that the wafer 2 is raised or lowered while supported horizontally from the bottom.

A support tube 123 is affixed on the outer side of the elevator shaft 120 on the upper surface of the bottom plate 115. A cooling plate 124 is affixed horizontally on the upper surface of the support tube 123.

A first heater lamp group 125 and a second heater lamp group 126 made up of numerous heating lamps are arrayed above the cooling plate 124 in order from the bottom, and affixed horizontally respectively. The first heater lamp group 125 and the second heater lamp group 126 are respectively supported horizontally by a first support pillar 127 and a second support pillar 128.

A power supply cable 129 for the first heater lamp group 125 and the second heater lamp group 126 is inserted through the bottom plate 115 and drawn out to the outside.

A turret 131 in the processing chamber 111 is installed concentrically with the processing chamber 111. The turret 131 is fastened in the same concentric circle on the upper surface of an inner tooth spur gear 133. This inner tooth spur gear 133 is supported horizontally on the bottom plate 115 by bearings 132.

A drive side spur gear 134 engages with the inner tooth spur gear 133. This drive side spur gear 134 is horizontally supported on the bottom plate 115 by bearings 135. A susceptor rotator device 136 installed below the bottom plate 115 drives the drive side spur gear 134 in a rotating movement.

An outer platform 137 formed from a flat plate in a circular ring shape is affixed horizontally on the upper end surface of the turret 131. An inner platform 138 is affixed horizontally on the inner side of the outer platform 137.

A susceptor 140 is supported on the bottom section on the inner circumference of the inner platform 138 by being engaged with an engaging section 139 affixed facing inwards along the radius. Insertion holes 141 are formed respectively at positions opposite each of the lifter pins 122 of the susceptor 140.

An annealing gas supply pipe 142 and an inert gas supply pipe 143 are respectively connected to the top plate 114 so as to communicate with the processing chamber 111.

Multiple probes 144 for radiation thermometers are inserted into the top plate 114, facing the top surface of the wafer 2 at respectively offset positions along the radius to the periphery from the center of the wafer 2. The radiation thermometer sends the temperature measurements one after another to the controller based on the radiant light detected by the respective multiple probes 144.

A radiation rate measuring device 145 is installed to make non-contact measurement of the radiation rate of the wafer 2 at other position on the top plate 114. This radiation rate measuring device 145 includes a reference probe 146. The reference probe 146 is rotated by a reference probe motor 147 within a perpendicular plane.

A reference lamp 148 for irradiating reference light onto the upper side of the reference probe 146 is installed so as to face the tip of the reference probe 146. This reference probe 146 is optically connected to the radiation thermometer. The radiation thermometer calibrates the measured temperature by comparing the photon density of the reference light from the reference lamp 148 with photon density from the wafer 2.

The annealing step shown in FIG. 1 is described next for the case where utilizing the above RTF apparatus to perform annealing on the nitrided hafnium silicate film formed on the wafer 2.

When the gate valve 118 opens, the negative pressure transfer device 13 carries the wafer 2 for annealing from the water carry-in/out port 117 into the processing chamber 111 of the RTF apparatus 110 serving as the second processing unit 33, and transfers it to the top end of the multiple lifter pins 122.

When the negative pressure transfer device 13 that transferred the wafer 2 onto the lifter pins 122, retreats outside the processing chamber 111, the gate valve 118 closes the wafer carry-in/out port 117.

The elevator drive device 119 lowers the elevator shaft 120 to deliver the wafer 2 on the lifter pins 122 to the susceptor 140.

The processing chamber 111 is exhausted through the exhaust port 116 to reach a specified pressure from 10 Pa to 10, 000 Pa while the processing chamber 111 is shut in an airtight stage.

When the susceptor 140 receives the wafer 2, the susceptor rotator device 136 rotates the turret 131 holding the wafer 2 on the susceptor 140, by way of the inner tooth spur gear 133 and the drive side spur gear 134.

While the susceptor rotator device 136 is rotating the wafer 2 held on the susceptor 140, the first heating lamp group 125 and the second heating lamp group 126 heat the wafer 2 to a specified range within 600 to 1000 degrees C.

The annealing gas supply pipe 142 supplies gas containing oxygen atoms such as oxygen gas, or gas containing nitrogen atoms such as ammonia gas or nitrogen gas into the processing chamber 111 during this rotation and heating.

The gas that the annealing gas supply pipe 142 supplies to the processing chamber 111 during the annealing is preferably an inert gas such as nitrogen gas. If adding oxygen gas, then the oxygen concentration inside the processing chamber 111 is preferably 0.1% to 0.5%, and the oxygen partial pressure is preferably 1.33 Pa to 6.65 Pa.

The first heating lamp group 125 and the second heating lamp group 126 uniformly heat the wafer 2 held on the susceptor 140 while the susceptor rotator device 136 is rotating the susceptor 140 so that the nitrided hafnium silicate film 8 on the wafer 2 is uniformly annealed across the entire surface of the film.

The processing time for this annealing is 5 to 120 seconds.

The above annealing step forms an improved nitrided hafnium silicate film 9 by post-annealing on the wafer 2 as shown in FIG. 6D.

When a specified, preset processing time elapses on the RTF apparatus 110, after the processing chamber 111 is exhausted through the exhaust port 116 to reach a specified negative pressure, the gate valve 118 opens and the negative pressure transfer device 13 carries the annealed wafer 2 from the processing chamber 111 into the negative pressure transfer chamber 11 in a sequence that is the reverse of the loading operation (wafer unloading).

After performing the high dielectric constant film forming step, the plasma nitriding step, and the annealing step, the wafer may then be cooled if necessary by using the first cooling unit 35 or the second cooling unit 36.

In the wafer unloading step shown in FIG. 1 after annealing in the cluster apparatus 100, the gate valve 18B opens the negative pressure transfer chamber 11 side of the carry-out chamber 15. The negative pressure transfer device 13 transfers the wafer 2 from the negative pressure transfer chamber 11 to the carry-out chamber 15, and transfers the wafer onto the temporary carry-out chamber placement stand of the carry-out chamber 15.

At this time, the gate valve 18A closes the positive pressure transfer chamber 16 side of the carry-out chamber 15 in advance, and an exhaust device (not shown in drawing) exhausts the carry-out chamber 15 to a negative pressure. When the carry-out chamber 15 is depressurized to the preset pressure value, the gate valve 18B opens the negative pressure transfer chamber 11 side of the carry-out chamber 15, and the wafer unloading step is performed.

The gate valve 18B is closed after the wafer unloading step.

The unloading operation from the third processing unit 33 to the carry-out chamber 15 via the negative pressure transfer chamber 11 for the wafer 2 whose processing in the annealing step is complete is implemented while the third processing unit 33, the negative pressure transfer chamber 11, and the carry-out chamber 15 are maintained in a vacuum. The generating of a natural oxidation film on the film surface of the wafer 2, or adhering of impurities or foreign objects such as organic compounds to the film surface of the wafer 2 is therefore prevented during unloading operation of the wafer 2 from the third processing unit 33 to the carry-out chamber 15.

In the same way, during all cases of carry-in of the wafer from the carry-in chamber 14 to the first processing unit 31, from the first processing unit 31 to the second processing unit 32, from the second processing unit 32 to the third processing unit 33, the transfer operations are all performed in a state where a vacuum is maintained so that the generating of a natural oxidation film on the film surface of the wafer 2, or adhering of impurities or foreign objects such as organic compounds to the film surface of the wafer 2 is prevented.

The first processing unit 31 performs the high dielectric constant film forming step, the second processing unit 32 performs the plasma nitriding step, and the third processing unit 33 performs the annealing step in sequence on the wafers 2 that were loaded in batches of 25 each to the carry-in chamber 14 by repeating the above operations.

After processing of the wafer 2 ends in the first processing unit 31, and the wafer is carried into the second processing unit 32, the next wafer 2 is transferred to the first processing unit 31 and can be processed.

In other words, after each processing unit is emptied during the consecutive processing sequence, the next wafer 2 is carried in and the multiple wafers can be processed in parallel.

When the consecutive specified processing of the 25 wafers 2 is completed, the processed wafers 2 accumulate on the temporary placement stand for the carry-in chamber 15.

In the wafer discharging step shown in FIG. 1, nitrogen gas is supplied into the carry-out chamber 15 maintained at a negative pressure, and after the interior of the carry-out chamber 15 reaches atmospheric pressure, the gate valve 18A opens the positive pressure transfer chamber 16 side of the carry-out chamber 15.

Next, the cap fitter/remover 26 of the pod opener 24 opens the cap of the empty pod 1 on the placement stand 25.

The positive pressure, transfer device 19 of the positive pressure transfer chamber 16 picks up the wafer 2 from the carry-in chamber 15 and carries it out to the positive pressure transfer chamber 16, and charges it in the pod 1 by way of the wafer carry-in/out port 23 of the positive pressure transfer chamber 16.

When storage of the processed 25 wafers 2 into the pod 1 is complete, the cap fitter/remover 26 of the pod opener 24 fits the cap of the pod 1 onto the wafer, loading/unloading opening and the pod 1 is then closed.

In the present embodiment, the wafer 2 whose processing was finished in the consecutive three steps in the cluster apparatus 10 is transferred while stored in an air-tight state in the pod 1 to the film-forming device for performing the gate electrode film forming step in the in-process transfer step for the pod shown in FIG. 1.

The film forming device for performing the gate electrode film forming step is for example the batch type vertical warm wall CVD apparatus, the single wafer ALD apparatus, or the single wafer CVD apparatus, etc.

After completing the patterning step shown in FIG. 1, an electrode with a dual metal gate structure is formed on the wafer 2.

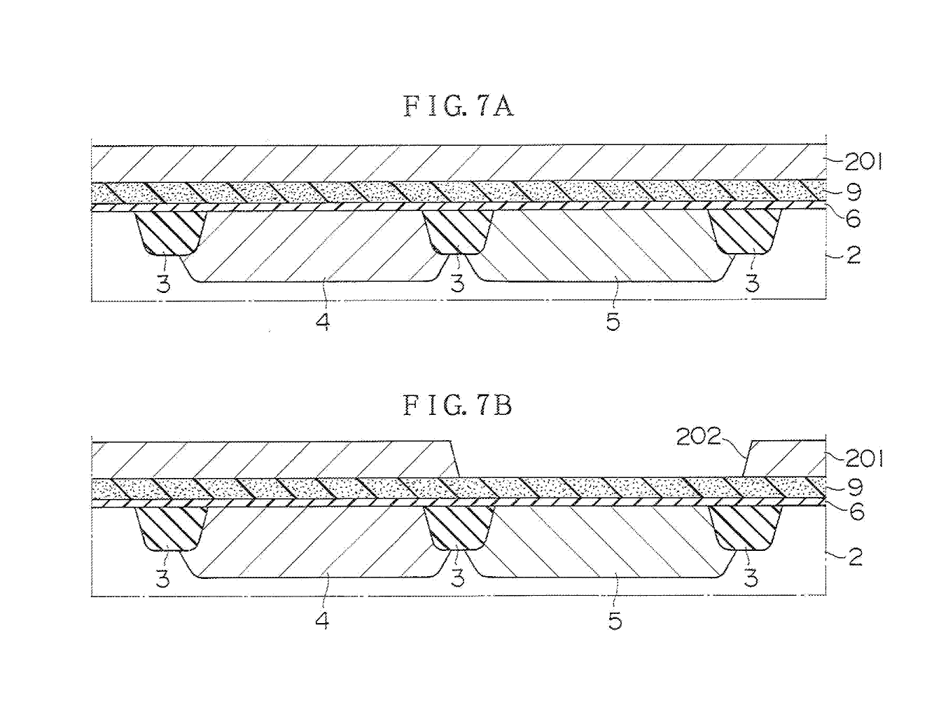

One example of the patterning step and the gate electrode film forming step is described next using FIG. 7 through FIG. 9 for the case where forming a dual metal gate structure electrode.

An NMOS electrode film 201 is formed on the nitrided hafnium silicate film 9 formed by the three consecutive steps in the cluster apparatus 10 as shown in FIG. 7A.

Next as shown in FIG. 7B, the section corresponding to the N well region 5 on the HMOS electrode film 201 is stripped away by etching, to form a throughole 202.

Forming this throughhole 202 exposes the bottom surface or namely the surface of the nitrided hafnium silicate film 9, and this bare section may be exposed to air. In the conventional art, this state presented the problem that nitrogen leaves from the nitrided hafnium silicate film 9.

However, in the present embodiment, the nitrided hafnium silicate film 9 has been improved by annealing so that nitrogen is prevented from leaving from the nitrided hafnium silicate film 9.

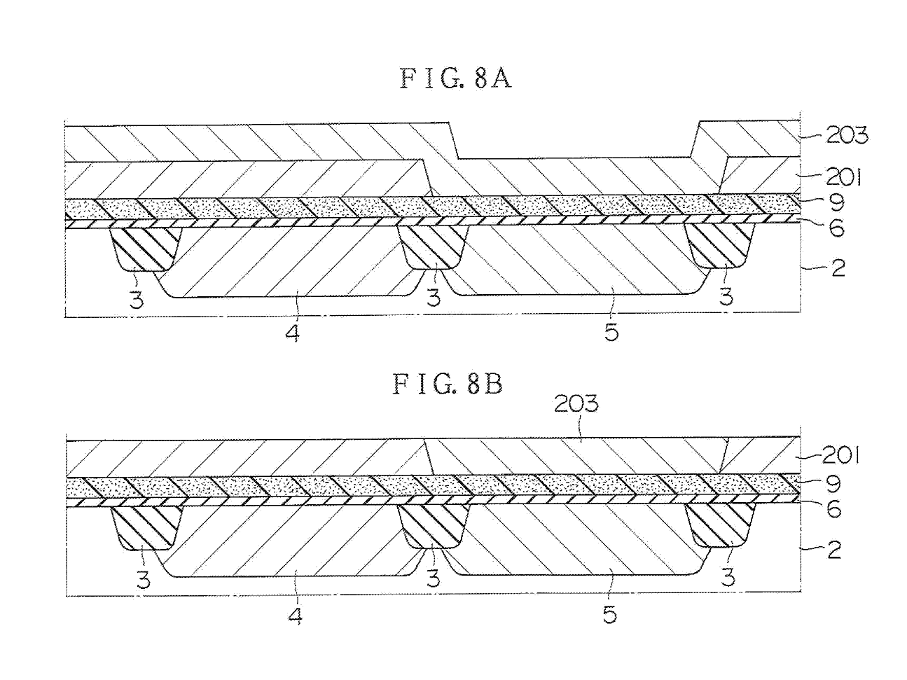

As shown in FIG. 8A, a PMOS electrode film 203 is next formed on the nitrided hafnium silicate film 9 that was exposed by forming the through hole 202 and the NMOS electrode film 201.

This PMOS electrode film 203 is next planarized until the NMOS electrode film 201 is exposed as shown in FIG. 8B.

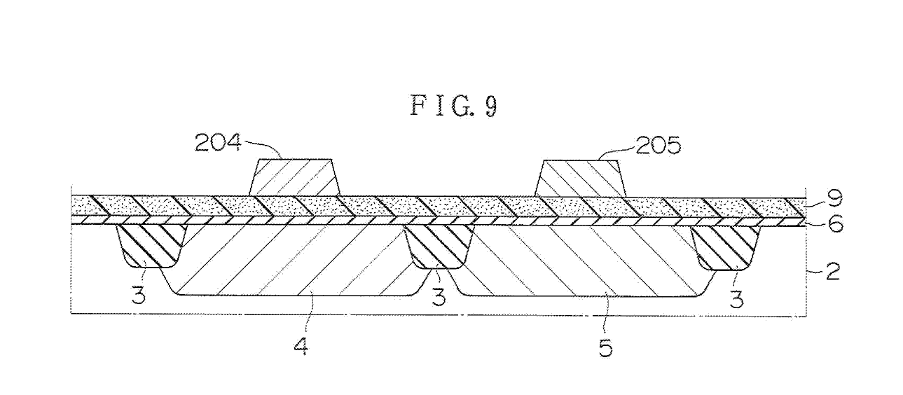

The NMOS electrode film 201 and the PMOS electrode film 203 are then patterned as shown in FIG. 9 to respectively form a PMOS electrode film 205 and an NMOS electrode 204.

The gate electrode is not limited to the dual metal gate structure.

Moreover, the gate electrode is not limited to being formed as metal gate electrodes, and for example may be formed from polysilicon film or amorphous silicon film.

The material for forming the metal electrodes is TiN, TaN, NiSi, PtSi, TaC, TiSi, Ru, or SiGe, etc.

The embodiment renders the following effects.

(1) Nitrogen supplied to the hafnium silicate film by plasma nitriding leaves when the film is exposed to the atmospheric air due to the weak bond with the atoms in the film. However, annealing the film after nitriding acts to strengthen the bond due to a reaction with the atoms in the film. Therefore, annealing the plasma-nitrided hafnium silicate film (in other words, nitrided hafnium silicate film) can prevent nitrogen from leaving from the plasma-nitrided hafnium silicate film improved by annealing, even if the wafer is exposed to air.

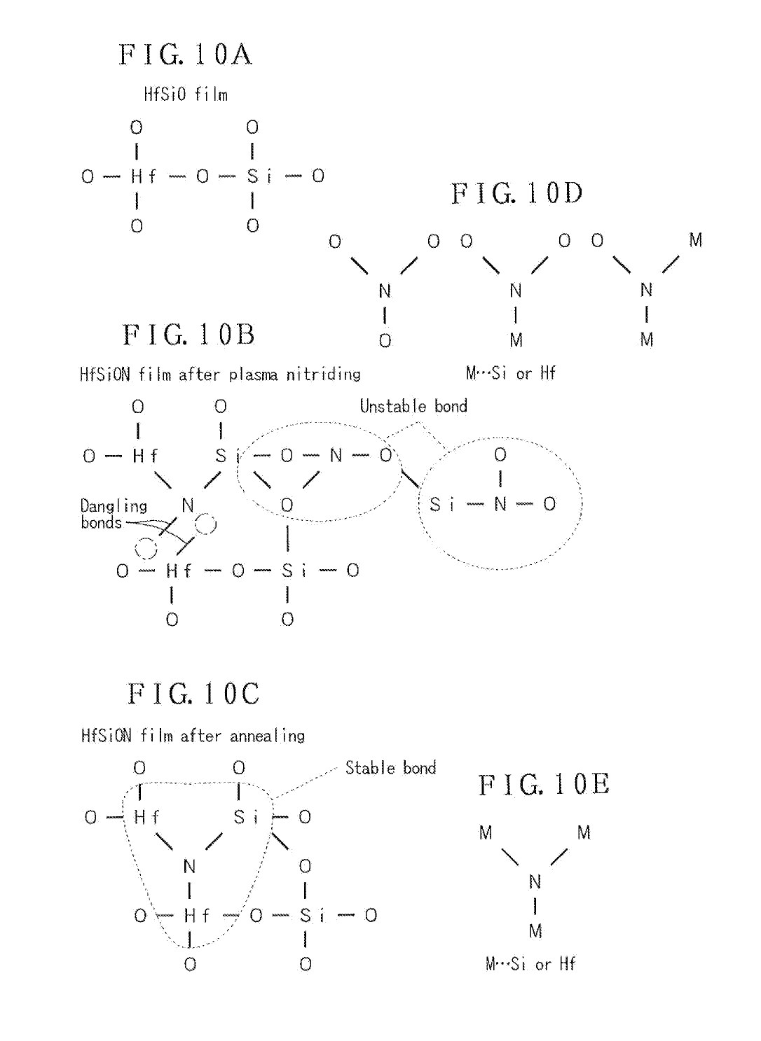

As shown in the structural formula here shown in FIG. 10A, atoms (Hf, Si, O) making up the hafnium silicate film are each covalently bonded.

However, plasma nitriding of this hafnium silicate film causes defects or namely unstable bonding or dangling bonds due to nitrogen ions that occur during the plasma nitriding in the nitrided hafnium silicate film generated by plasma nitriding as can be seen in the structural formula shown in FIG. 10B.

As shown in FIG. 10D, these unstable bonds are bonds including bonds of N atoms and O atoms (N—O bonds). Namely, these are bonds where an N atom bonds with three O atoms, with Si atoms or Hf atoms set as the M atoms, bonds where an N atom and two O atoms and one M atom bond, and bonds where an N atom and one oxygen atom and two M atoms bond.

Bonds that include these type of N—O bonds have weak bonding force, and the atoms making up this bond leave when exposed to air. Dangling bonds are also included as unstable bonds.

If hafnium silicate film is nitrided such as by NH₃ annealing, then defects such as unstable bonding will occur, however, plasma nitriding causes more defects to occur than thermal nitriding.

Annealing the nitrided hafnium silicate film where these type of defects occur, repairs the defects by way of the high-temperature processing. In other words, atoms in the film that make up these unstable bonds leave or bond with another element, the N—O bonds then become fewer in number, the N—M bonds increase, and the bonds between M atoms and other atoms in the film become stable and stronger. The bonds of atoms (HF, Si, O, N), making up the nitrided hafnium silicate film are consequently stabilized as shown by the structural formulas in FIG. 10C.

Stable bonds are bonds not containing N—O bonds as shown in FIG. 10E, namely bonds between an N atom and three M atoms.

(2) By annealing immediately without exposing the wafer to air after plasma nitriding of the hafnium silicate film, nitrogen can be prevented from leaving from the nitrided hafnium silicate film that was improved by annealing so that the nitrogen concentration can be maintained at the specified value after processing (after plasma nitriding).

(3) Maintaining the nitrogen concentration at the specified value in the nitrided hafnium silicate film can prevent losing or lowering the merits of plasma nitriding such as suppression of crystallization and a low leakage current.

(4) The processing temperature during annealing of plasma nitrided hafnium silicate film is preferably set to 1000 degrees C. or more,

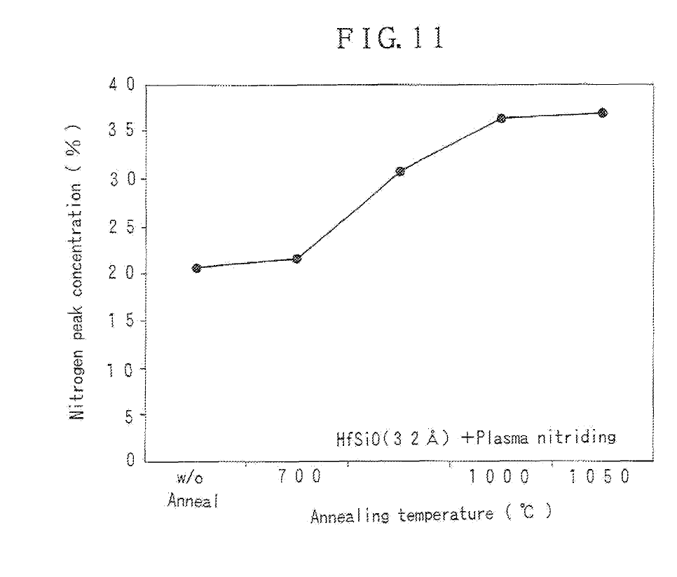

FIG. 11 is a graph showing the interrelation of the nitrogen concentration in the film and the annealing temperature during annealing of the plasma nitrided hafnium silicate film.

The horizontal axis in the graph of FIG. 11 is the annealing temperature (in degrees C.) and the vertical axis is the nitrogen concentration (in percent) in the film.

The higher the annealing temperature, the more a drop in the nitrogen concentration can be suppressed as shown in FIG. 11. Examining FIG. 11 also shows that raising the annealing temperature to 1000 degrees C. or more causes fluctuations on the nitrogen concentration to become more fixed values.

(5) High temperature annealing performed in an atmosphere containing large quantities of oxygen forms a silicon oxide film at the interface between the high dielectric constant film and the silicon wafer, making the film thicker overall. Therefore, an inert gas such as nitrogen gas should preferably be the main constituent in the annealing atmosphere, and if adding oxygen, then the oxygen concentration should preferably be set in a range from 0.1% to 0.5%, and the oxygen partial pressure in a range from 1.33 Pa to 6.65 Pa.

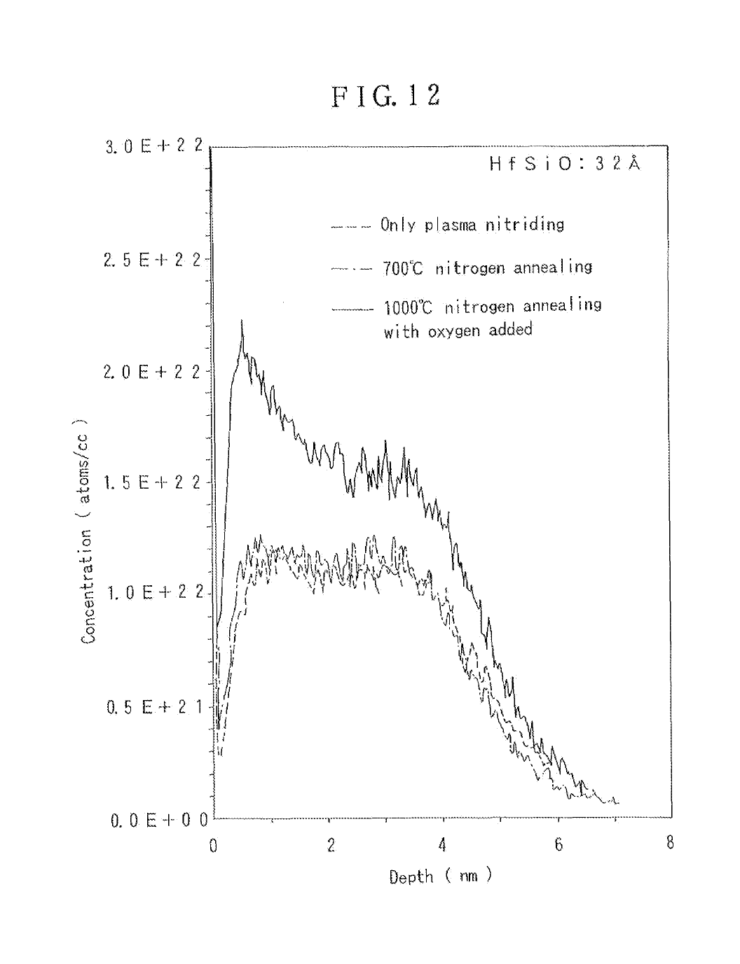

FIG. 12 is a graph showing the nitrogen distribution in the nitrided hafnium silicate film that was left standing in air for a period of five days after forming the film.

In FIG. 12, the horizontal axis shows the depth (nm) from the surface of the nitrided hafnium silicate film and the vertical axis shows the nitrogen concentration (atoms/cc).

In FIG. 12, the broken line shown by “Only plasma nitriding” is the case where the hafnium silicate film was only subjected to plasma nitriding. The chain line showing the “700 degrees C. nitrogen annealing” is annealing performed under a nitrogen gas environment at an annealing temperature of 700 degrees C. and a pressure of 1333 Pa after plasma nitriding of the hafnium silicate film. The solid line shown by “1000 degrees C. nitrogen annealing with oxygen added” is annealing performed under an environment where the main constituent of the atmosphere is nitrogen gas added with oxygen at a pressure of 1333 Pa and an annealing temperature of 1000 degrees C., and at an oxygen concentration of 0.1% to 0.5%, oxygen partial pressure of 1.33 Pa to 6.65 Pa, after plasma nitriding of the hafnium silicate film.

Examining FIG. 12 reveals that the nitrogen concentration when 1000 degrees C. nitrogen annealing with oxygen added was performed is higher compared to the case when only plasma nitriding was performed and the case where 700 degrees C. nitrogen annealing was performed; and also shows that a drop in the nitrogen content can be suppressed.

Adding a tiny amount of oxygen to an atmosphere whose main constituent is inert gas during annealing or in other words setting the oxygen concentration to 0.1% to 0.5%, and oxygen partial pressure at 1.33 Pa to 6.65 Pa was confirmed to improve the mobility in the transistor.

(6) The elimination of nitrogen and a drop in the nitrogen content can be almost completely suppressed by annealing the wafer with no exposure to air immediately after plasma nitriding of the hafnium silicate film even if the High-K film is exposed to air after the processing sequence. Therefore, there is no need to protect the wafer from air after the processing sequence, and in atmospheres including air or in other words a state exposed to air, the wafer can he transferred, the wafer stored in a pod, and the pod storing the wafers can be transferred to other apparatus (electrode forming apparatus).

In other words, when transferring the wafer into the pod from the carry-out chamber by way of the positive pressure transfer chamber, there is no need to contrive measures such as nitrogen purging of the space (within the carry-out chamber, within the positive pressure transfer-chamber and within the pod) where the wafer is transferred; nitrogen purging inside of the pod where the wafers are stored after transferring the wafer; sealing of nitrogen gas inside the pod where the wafers are stored; or improving of the pod structure, etc.

The nitrogen purging inside of the carry-out chamber, inside of the positive pressure transfer chamber and inside of the pod; and the time for sealing nitrogen gas inside the pod can be eliminated, moreover the cost required for improving the pod structure can also be lowered.

In the present embodiment, the case was described where an interfacial layer or namely the interfacial silicon oxide film 6 of FIG. 6A was formed in advance on the surface of the wafer 2, the wafer 2 formed with this interfacial layer then loaded into the cluster apparatus 10, and three steps including the high dielectric constant film forming step, plasma nitriding step, and annealing step were performed. However, the interfacial layer may be formed in the cluster apparatus 10.

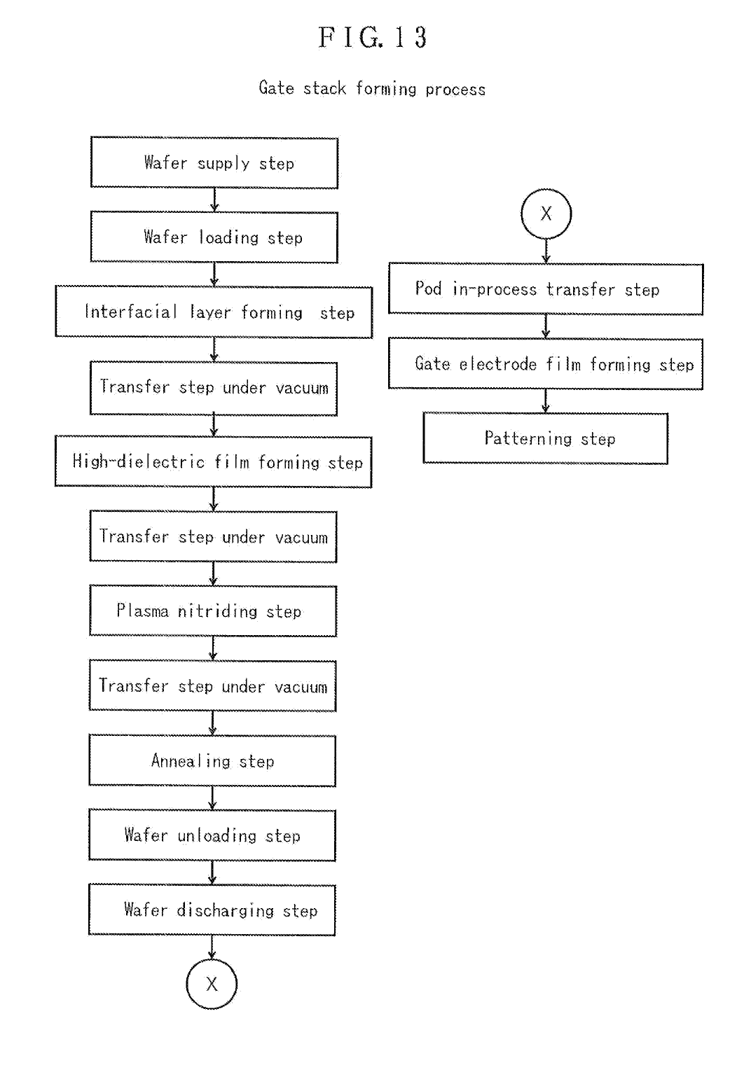

In other words, after loading the wafer 2 into the cluster apparatus 10 as shown in FIG. 13, the cluster apparatus 10 may consecutively perform the four steps made up of the inter-facial layer forming step, high dielectric constant film forming step, plasma nitriding step, and annealing step.

In this case, the interfacial layer may be formed by thermal oxidizing using O₂ by the RTF apparatus 110 serving as the third processing unit 33, or formed by the ALD apparatus 40 serving as the first processing unit 31 and utilizing an oxidizer agent such as O₃.

Processing conditions when forming the interfacial layer with the third processing unit 33 (RTP apparatus 110) are described as a temperature of 700 to 900 degrees C., pressure of 133 Pa to 13332 Pa, and gas type of oxygen (O₂) or nitric oxide (NO).

Processing conditions when forming the interfacial layer with the first processing unit 31 (ALD apparatus 40) are described as a temperature of 350 to 450 degrees C., pressure of 50 Pa to 200 Pa, and gas type of ozone (O₃).

The wafer can be treated in the specified process by maintaining each of the processing conditions at fixed values within their respective ranges.

When forming the interfacial layer with the first processing unit 31 (ALD apparatus 40), the wafer 2 path in the cluster apparatus 10 is: the first processing unit 31 (ALD apparatus 40)→the second processing unit 32 (MMT apparatus 70)→the third processing unit 33 (RTP apparatus 110) the same as the previous embodiment.

When forming the interfacial layer with the third processing unit 33 (RTP apparatus 110), the wafer 2 path in the cluster apparatus 10 is: the third processing unit 33 (RTP apparatus 110)→the first processing unit 31 (ALD apparatus 40)→the second processing unit 32 (MMT apparatus 70)→the third processing unit 33 (RTP apparatus 110).

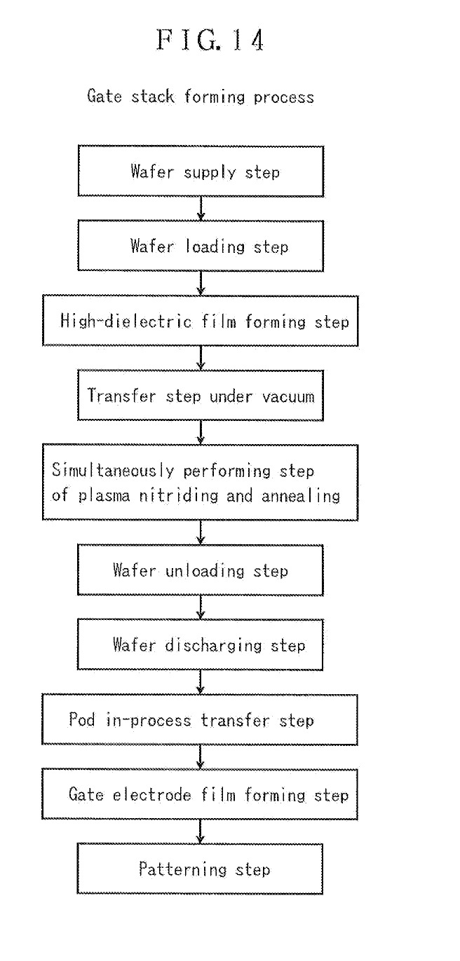

FIG. 14 is a flow chart showing the MOSFET gate stack forming process in the method for producing ICs in another embodiment of the present invention.

This embodiment differs from the previous embodiment in the point that the plasma nitriding step and the annealing step are performed simultaneously.

In other words, the transfer step under a vacuum between the plasma nitriding step and the annealing step is omitted. The other steps are identical to the previous embodiment.

The process for forming the MOSFET gate stack in the IC production method of this embodiment described hereafter differs from the process for forming the MOSFET gate stack in the IC production method of the previous embodiment. Namely, the step where the plasma nitriding and annealing are performed simultaneously is mainly described.

In the IC production method of this embodiment, the MOSFET gate stack forming process is also performed using the cluster apparatus 10 of the previous embodiment.

The gate valve 44 opens when forming of the hafnium silicate film is finished, and the negative pressure transfer device 13 carries out the wafer 2 whose film-forming is complete, from the first processing unit 31 to the negative pressure transfer chamber 11 maintained at a negative pressure (wafer unloading).

The gate valve 82 next opens after the gate valve 44 is closed, and the negative pressure transfer device 13 transfers the wafer 2 to the MMT apparatus 70 serving as the second processing unit 32 and loads it into the processing chamber as shown in FIG. 14 (wafer loading).

The exhaust device 80 then exhausts the interior of processing chamber 71 to reach a specified pressure in a range from 0.5 to 10 Pa while the processing chamber 71 is maintained in an airtight state.

The heater 90a of the susceptor 90 carries out preheating, to heat the wafer 2 held in the susceptor 90 to a specified processing temperature of 700 degrees C. or higher.

When the wafer 2 is heated to the processing temperature, the gas supply device 78 feeds a gas containing nitrogen atoms such as nitrogen gas (N₂) or ammonia (NH₃) gas at a flow rate of 0.1 SLM to 2 SLM by way of the gas supply line 79 and the gas spray holes 77 of the shower plate 76 into the processing chamber 71 in a shower state.

The high-frequency RF power supply 86 next applies high frequency (RF) power of 50 to 700 watts to the tubular-elect rode 84 by way of the impedance matcher 85. The impedance matcher 85 controls the RF power so that the reflected wave is minimal.

Magnetron discharge occurs due to the effects of the magnetic field of the tubular magnets 87, 87, and the charge is trapped in the space above the wafer 2, generating a high density plasma in the plasma generating region 83.

The surface of the wafer 2 on the susceptor 90 is then plasma-nitrided by this high density plasma that was generated.

Defects occur in the plasma nitrided hafnium silicate film as described above, due to nitrogen ions as shown in a structural formula shown in FIG. 10B. However, when this nitrided hafnium silicate film is annealed, the defects are repaired and the bonding of atoms forming the nitrided hafnium silicate film stabilizes as shown by the structural formula in FIG. 10C.

During plasma nitriding of the wafer 2 in this embodiment, by the high density plasma generated in the space above the wafer 2, the wafer 2 is heated by the heater 90a of the susceptor 90 to a high temperature of 700 degrees C. or more so that the plasma nitriding progresses simultaneously while the defects formed by the plasma nitriding are repaired.

In other words, defects as shown in the structural formula shown in FIG. 10B occur due to nitrogen ions in the plasma nitrided hafnium silicate film but defects repairing actions that cause the elimination of unstable bonded atoms, or bond with another elements progress simultaneously with the plasma nitriding during plasma niriding since the wafer 2 is heated to a high temperature of 700 degrees C. or more. The bonding of atoms making up the nitrided hafnium silicate film therefore stabilizes as shown by the structural formula in FIG. 10C.

When the heating temperature of the wafer 2 or in other words the processing temperature rises excessively during this plasma nitriding step, the diffusion of nitrogen into the interface between the silicon wafer and the hafnium silicate film serving as the high dielectric constant film speeds up, so that the interface becomes excessively nitrided, causing the MOSFET characteristics to deteriorate. In view of this deterioration, the processing temperature is preferably set to 900 degrees C. or less.

On the other hand, when the reaction of the nitrogen species supplied to the hafnium silicate film serving as the high dielectric constant film is low during this plasma nitriding step at a high temperature of 700 to 900 degrees C., then the nitrogen might diffuse in large amounts into the interface between the silicon wafer and the hafnium silicate film without bonding to the hafnium silicate film. Therefore, it is essential that the plasma processing apparatus supply a nitrogen species possessing high reactivity to the wafer.

Therefore, as shown in this embodiment, the MMT apparatus 70 capable of forming the high-density plasma generating region 83 of the high density plasma in the space above the wafer 2 is preferable rather than a remote plasma processing apparatus.

Moreover, using the MMT apparatus 70 allows sufficiently nitriding of the hafnium silicate film with high-density plasma even in low to intermediate temperature-regions from 100 to 700 degrees C.

This embodiment repairs defects occurring in the hafnium silicate film, due to plasma nitriding while suppressing excessive nitriding at the interface between the silicon wafer and the hafnium silicate film as already described by using processing conditions specified as a temperature of 700 to 900 degrees C., pressure of 0.5 Pa to 10 Pa, preferably 0.5 Pa to 2 Pa, and gas type of nitrogen (N₂) or ammonia (NH₃), and the specified processing is performed on the wafer by maintaining the respective processing conditions at fixed values within their respective ranges.

The gate valve 82 opens after the preset processing time for the MMT apparatus 70 elapses, and along with the forming of a nitrided hafnium silicate film, the negative pressure transfer device 13 carries out the wafer 2 whose film defects were repaired, from the processing chamber 71 into the negative pressure transfer chamber 11.

Next, as shown in FIG. 14, after closing the gate valve 82, the negative pressure transfer device 13 transfers the wafer 2 to the carry-out chamber 15 without transferring it to the third processing unit 33 for the annealing step, and loads the wafer 2 onto the carry-out chamber temporary placement stand of the carry-out chamber 15 (wafer discharging step).

In this embodiment, the plasma nitriding progresses simultaneously with the repairing of defects as already described, so that the step of transferring the wafer under a vacuum after the plasma nitriding step can be omitted. Moreover, a dedicated processing unit (for example RTP apparatus 110) for performing the annealing step can also be eliminated.

The present invention is not limited by the above embodiments and needless to say, all manner of changes or adaptations not departing from the spirit and scope of the invention are allowed.

A MOSFET gate stack forming process was described in the above embodiment, however, the same effects can be obtained by applying this present invention to capacitor forming processes for memories such as DRAM including the upper metal electrode forming step, capacitor insulating film forming step, and the barrier metal forming step, on the wafer formed with a lower metal electrode.

The materials for forming the capacitor upper electrode are Al, TiN, or Ru.

The electrode forming gas used in the electrode forming step may be selected as needed according to the desired electrode forming material.

The material for forming the high dielectric constant film is not limited to nitrided hafnium silicate (HfSiON).

Other materials available for forming a high dielectric constant film for forming the gate insulating film are ZrON, HfAlON, LaON, or YON.

The substrate for processing is not limited to wafers and may include substrates such as glass substrates and liquid crystal panels in LCD device manufacturing processes.

The preferred aspects of the present, invention are described as follows.
(1) A semiconductor device manufacturing method comprising the steps of:

nitriding a high dielectric constant film formed on a substrate by using plasma,

heat treating the nitrided high dielectric constant film, and

transferring the heat treated substrate,

wherein the nitriding step and the heat treating step are performed consecutively or simultaneously in the same substrate processing apparatus without exposing the substrate to air, and the step of transferring the substrate is performed while the substrate is exposed to air.
(2) The semiconductor device manufacturing method according to the above first (1) aspect, wherein nitrogen ions are utilized as the main constituent of the substance for causing the nitriding in the nitriding step.
(3) The semiconductor device manufacturing method according to the above first (1) aspect, wherein the nitriding step and the beat treating step are performed consecutively, the heat treating step is performed at a temperature of 1000 degrees C. or higher and in an atmosphere with inert gas as the main constituent, oxygen gas is further added to the atmosphere, and the oxygen gas partial pressure in the atmosphere is 1.33 Pa to 65 Pa.
(4) The semiconductor device manufacturing method according to the above second (2) aspect, wherein the nitriding step and the heat treating step are performed simultaneously, and the nitriding is performed at that time while repairing defects occurring due to the nitrogen ions in the high dielectric constant film by the effect from the heat treating.
(5) The semiconductor device manufacturing method according to the above first (1) aspect, wherein the step of transferring the substrate includes a step of storing the heat treated substrate in a substrate storage container, and the substrate is exposed to air in the step of storing the substrate.
(6) The semiconductor device manufacturing method according to the above first (1) aspect, wherein the step of transferring the substrate includes a step of storing the heat treated substrate in a substrate storage container, and a step of transferring the substrate storage container storing the substrate to another substrate processing apparatus, and the substrate is exposed to air in at least one of the step of storing the substrate and the step of transferring the substrate storage container.

(7) A semiconductor device manufacturing method comprising the steps of:

forming a high dielectric constant film on a substrate,

nitriding the high dielectric constant film by using plasma,

heat treating the nitrided high dielectric constant film, and

transferring the heat treated substrate,

wherein the step of forming the high dielectric constant film, the nitriding step and the heat treating step are performed consecutively in the same substrate processing apparatus without exposing the substrate to air, and the step of transferring the substrate is performed while the substrate is exposed to air.
(8) A semiconductor device manufacturing method comprising the steps of:

forming an interfacial layer on a substrate,

forming a high dielectric constant film on the interfacial layer,

nitriding the high dielectric constant film by using plasma,

heat treating the nitrided high dielectric constant film, and

transferring the heat treated substrate,

wherein the step of forming the interfacial layer, the step of forming the high dielectric constant film, the nitriding step and the heat treating step are performed consecutively in the same substrate processing apparatus without exposing the substrate to air, and the step of transferring the substrate is performed while the substrate is exposed to air.
(9) A semiconductor device manufacturing method comprising the steps of:

nitriding a high dielectric constant film formed on a substrate by using plasma,

heat treating the nitrided high dielectric constant film,

forming an electrode film on the heat treated high dielectric constant film,

exposing a portion of the high dielectric constant film by removing a portion of the electrode film, and

transferring the substrate in a state where a portion of the high dielectric constant film is exposed,

wherein at least the nitriding step and the heat treating step are performed consecutively or simultaneously in the same substrate processing apparatus without exposing the substrate to air, and the step of transferring the substrate with a portion of the high dielectric constant film exposed is performed while the substrate is exposed to air.
(10) A semiconductor device manufacturing method comprising the steps of:

forming a high dielectric constant film on a substrate, and

nitriding the high dielectric constant film by using plasma while heating the substrate,

wherein in the nitriding step, nitrogen ions are utilized as the main constituent of the substance for causing the nitriding, and the nitriding is performed at the nitriding processing temperature of performing the nitriding while repairing defects occurring due to the nitrogen ions in the high dielectric constant film.
(11) The semiconductor device manufacturing method according to the above tenth (10) aspect, wherein in the nitriding step, the nitriding is performed at a processing temperature of 700 to 900 degrees C.
(12) The semiconductor device manufacturing method according to the above tenth (10) aspect, wherein after the nitriding step, an electrode film is formed on the nitrided high dielectric constant film, without heat treating the nitrided high dielectric constant film.
(13) A substrate processing apparatus comprising:

a placement stand for mounting a substrate storage container for storing a substrate;

a prechamber that the substrate is carried in and carried out from;

a first processing chamber, a second processing chamber, and a third processing chamber for processing the substrate;

a first transfer chamber installed so as to connect in an airtight state to each of the prechamber, the first processing chamber, the second processing chamber and the third processing chamber, and including a first transfer-device for transferring the substrate between the prechamber, the first processing chamber, the second processing chamber and the third processing chamber;

a second transfer chamber installed between the placement stand and the prechamber, and including a second transfer device for transferring the substrate between the prechamber and the substrate storage container mounted on the placement stand; and

a controller for controlling the above components so that the controller controls a continuous sequence of operations without exposing the substrate to air that include forming a high dielectric constant film on the substrate in the first processing chamber; transferring the substrate formed with the high dielectric constant film by the first transfer device from the first processing chamber via the first transfer chamber to the second processing chamber; nitriding the high dielectric constant film formed on the substrate by using plasma in the second processing chamber; transferring the nitrided substrate by the first transfer device from the second processing chamber via the first transfer chamber to the third processing chamber; and heat treating the nitrided high dielectric constant film in the third processing chamber, and controls to transfer the substrate that underwent the successive operations by the second transfer device in an atmosphere containing air, from the prechamber via the second transfer chamber to the substrate storage container mounted on the placement stand.
(14) A substrate processing apparatus comprising:

a placement stand for mounting a substrate storage. container for storing a substrate;

a prechamber that the substrate is carried in and carried out from;

a first processing chamber and a second processing chamber for processing the substrate;

a first transfer chamber installed so as to connect in an airtight state to each of the prechamber, the first processing chamber and the second processing chamber, and including a first transfer device for transferring the substrate between the prechamber, the first processing chamber and the second processing chamber;

a second transfer chamber installed between the placement stand and the prechamber, and including a second transfer device for transferring the substrate between the prechamber and the substrate storage container mounted on the placement stand; and

a controller for controlling the above components so that the controller controls a continuous sequence of operations without exposing the substrate to air that include forming a high dielectric constant film on the substrate in the first processing chamber, transferring the substrate formed With the high dielectric constant film by the first transfer device from the first processing chamber via the first transfer chamber to the second processing chamber, nitriding the high dielectric constant film formed on the substrate by using plasma while heating the substrate in the second processing chamber wherein the processing pressure in the second processing chamber is set to a pressure where nitrogen ions are the main constituent of the substance for causing the nitriding, and the processing temperature is set to a temperature of performing the nitriding while repairing defects occurring due to the nitrogen ions in the high dielectric constant film, and controls to transfer the substrate that underwent the successive operations by the second transfer device in an atmosphere containing air, from the prechamber via the second transfer chamber to the substrate storage container mounted on the placement stand.

1. A semiconductor device manufacturing method comprising the steps of:
nitriding a high dielectric constant film formed on a substrate by using plasma,
heat treating the nitrided high dielectric constant film, and
transferring the heat treated substrate,
wherein the nitriding step and the heat treating step are performed consecutively or simultaneously in the same substrate processing apparatus without exposing the substrate to air, and the step of transferring the substrate is performed while the substrate is exposed to air.

2. The semiconductor device manufacturing method according to claim 1, wherein nitrogen ions are utilized as the main constituent of the substance for causing the nitriding in the nitriding step.

3. The semiconductor device manufacturing method according to claim 1, wherein the nitriding step and the heat treating step are performed consecutively, the heat treating step is performed at a temperature of 1000 degrees C. or higher and in an atmosphere with inert gas as the main constituent, oxygen gas is further added to the atmosphere, and the oxygen gas partial pressure in the atmosphere is 1.33 Pa to 6.65 Pa.

4. The semiconductor device manufacturing method according to claim 2, wherein the nitriding step and the heat treating step are performed simultaneously, and the nitriding is performed at that time while repairing defects occurring due to the nitrogen ions in the high dielectric constant film by the effect from the heat treating.

5. The semiconductor device manufacturing method according to claim 1, wherein the step of transferring the substrate includes a step of storing the heat treated substrate in a substrate storage container, and the substrate is exposed to air in the step of storing the substrate.

6. The semiconductor device manufacturing method according to claim 1, wherein the step of transferring the substrate includes a step of storing the heat treated substrate in a substrate storage container, and a step of transferring the substrate storage container storing the substrate to another substrate processing apparatus, and the substrate is exposed to air in at least one of the step of storing the substrate and the step of transferring the substrate storage container.

7. A semiconductor device manufacturing method comprising the steps of:
forming a high dielectric constant film on a substrate,
nitriding the high dielectric constant film by using plasma,
heat treating the nitrided high dielectric constant-film, and
transferring the heat treated substrate,
wherein the step of forming the high dielectric constant film, the nitriding step and the heat treating step are performed consecutively in the same substrate processing apparatus without exposing the substrate to air, and the step of transferring the substrate is performed while the substrate is exposed to air.

8. A semiconductor device manufacturing method comprising the steps of:
forming an interfacial layer on a substrate,
forming a high dielectric constant film on the interfacial layer,
nitriding the high dielectric constant film by using plasma,
heat treating the nitrided high dielectric constant-film, and
transferring the heat treated substrate,
wherein the step of forming the interfacial layer, the step of forming the high dielectric constant film, the nitriding step and the heat treating step are performed consecutively in the same substrate processing apparatus without exposing the substrate to air, and the step of transferring the substrate is performed while the substrate is exposed to air.

9. A semiconductor device manufacturing method comprising the steps of:
nitriding a high dielectric constant film formed on a substrate by using plasma,
heat treating the nitrided high dielectric constant film,
forming an electrode film on the heat treated high dielectric constant film,
exposing a portion of the high dielectric constant film by removing a portion of the electrode film, and
transferring the substrate in a state where a portion of the high dielectric constant film is exposed,
wherein at least the nitriding step and the heat treating step are performed consecutively or simultaneously in the same substrate processing apparatus without exposing the substrate to air, and the step of transferring the substrate with a portion of the high dielectric constant film exposed is performed while the substrate is exposed to air.

10. A semiconductor device manufacturing method comprising the steps of:
forming a high dielectric constant film on a substrate, and
nitriding the high dielectric constant film by using plasma while heating the substrate,
wherein in the nitriding step, nitrogen ions are utilized as the main constituent, of the substance for causing the nitriding, and the nitriding is performed at the nitriding processing temperature of performing the nitriding while repairing defects occurring due to the nitrogen ions in the high dielectric constant film.

11. The semiconductor device manufacturing method according to claim 10, wherein in the nitriding step, the nitriding is performed at a processing temperature of 700 to 900 degrees C.

12. The semiconductor device manufacturing method according to claim 10, wherein after the nitriding step, an electrode film is formed on the nitrided high dielectric constant film, without heat treating the nitrided high dielectric constant film.

13. A substrate processing apparatus comprising:
a placement stand for mounting a substrate storage container for storing a substrate;
a prechamber that the substrate is carried in and carried out from;
a first processing chamber, a second processing chamber, and a third processing chamber for processing the substrate;
a first transfer chamber installed so as to connect in an airtight state to each of the prechamber, the first processing chamber, the second processing chamber and the third processing chamber, and including a first transfer device for transferring the substrate between the prechamber, the first processing chamber, the second processing chamber and the third processing chamber;
a second transfer chamber installed between the placement stand and the prechamber, and including a second transfer device for transferring the substrate between the prechamber and the substrate storage container mounted on the placement stand; and
a controller for controlling the above components so that the controller controls a continuous sequence of operations without exposing the substrate to air that include forming a high dielectric constant film on the substrate in the first processing chamber; transferring the substrate formed with the high dielectric constant film by the first transfer device from the first processing chamber via the first transfer chamber to the second processing chamber; nitriding the high dielectric constant film formed on the substrate by using plasma in the second processing chamber; transferring the nitrided substrate by the first transfer device from the second processing chamber via the first transfer chamber to the third processing chamber; and heat treating the nitrided high dielectric constant film in the third processing chamber, and controls to transfer the substrate that underwent the successive operations by the second transfer device in an atmosphere containing air, from the prechamber via the second transfer chamber to the substrate storage container mounted on the placement stand.

14. A substrate processing apparatus comprising:
a placement stand for mounting a substrate storage container for storing a substrate;
a prechamber that the substrate is carried in and carried out from;
a first processing chamber and a second processing chamber for processing the substrate;
a first transfer chamber installed so as to connect in an airtight state to each of the prechamber, the first processing chamber and the second processing chamber, and including a first transfer device for transferring the substrate between the prechamber, the first processing chamber and the second processing chamber;
a second transfer chamber installed between the placement stand and the prechamber, and including a second transfer device for transferring the substrate between the prechamber and the substrate storage container mounted on the placement stand; and
a controller for controlling the above components so that the controller controls a continuous sequence of operations without exposing the substrate to air that include forming a high dielectric constant film on the substrate in the first processing chamber, transferring the substrate formed with the high dielectric constant film by the first transfer device from the first processing chamber via the first transfer chamber to the second processing chamber, nitriding the high dielectric constant film formed on the substrate by using plasma while heating the substrate in the second processing chamber, wherein the processing pressure in the second processing chamber is set to a pressure where nitrogen ions are the main constituent of the substance for causing the nitriding, and the processing temperature is set to a temperature of performing the nitriding while repairing defects occurring due to the nitrogen ions in the high dielectric constant film, and controls to transfer the substrate that underwent the successive operations by the second transfer device in an atmosphere containing air, from the prechamber via the second transfer chamber to the substrate storage container mounted on the placement stand.
